(19) United States
(12) Patent Application Publication
(10) Pub. No.: US 2024/0185914 A1
(43) Pub. Date: Jun. 6, 2024

(54) BITLINE TIMING-BASED MULTI-STATE PROGRAMMING IN NON-VOLATILE MEMORY STRUCTURES

(71) Applicant: SanDisk Technologies LLC, Addison, TX (US)

(72) Inventors: Ming Wang, Shanghai (CN); Liang Li, Shanghai (CN)

(73) Assignee: SanDisk Technologies LLC, Addison, TX (US)

(21) Appl. No.: 18/220,387

(22) Filed: Jul. 11, 2023

Related U.S. Application Data
(60) Provisional application No. 63/430,239, filed on Dec. 5, 2022.

(51) Int. Cl. G11C 11/56; G11C 7/12; G11C 8/08

(52) U.S. Cl. CPC G11C 11/5628; G11C 7/12; G11C 8/08

(57) ABSTRACT

A method for multi-state programming of a non-volatile memory structure, comprising: (1) initiating a programming operation with respect to multiple program states, (2) applying, to all selected word lines of the memory structure, a programming voltage bias (V_{PGM}) level pre-determined to be suitable for programming a highest program state of the multiple program states, wherein the programming voltage bias level is applied according to a given program pulse width, and (3) with respect to each program state other than the highest program state of the multiple program states, applying a zero-volt bitline voltage bias (V_{BL}) to one or more bitlines that are associated with one or more memory elements to be programmed to the program state, wherein the zero-volt bitline voltage bias is applied according to a respective program sub-pulse width that is less than the given program pulse width.

### CROSS-REFERENCE TO RELATED APPLICATIONS

This application claims the benefit of U.S. Provisional Application No. 63/430,239, filed on Dec. 5, 2022. The entire disclosure of the application referenced above is incorporated herein by reference.

### TECHNICAL FIELD

This disclosure relates to non-volatile memory storage systems in solid-state drives or other devices, including but not limited to flash drives or embedded/removable flash packages. More specifically, this disclosure relates to systems and methods for programming non-volatile memory structures.

### BACKGROUND

Due to emerging technology and market forces, solid-state drives (SSDs) are steadily replacing previously conventional data storage systems that rely on the rotation of magnetic mediums for reading and writing data (e.g., hard disk drives). Rather than comprising any mechanical or moving parts, solid-state memory comprises integrated circuit assemblies or interconnected flash components to provide non-volatile storage in which stored data can be persistently retained even during a planned or unplanned interruption of power. As a result, a solid-state drive is inherently faster and more robust (i.e., less susceptible to data loss and corruption), as well as consumes less power and is more compact in comparison to disk-based storage. Accordingly, non-volatile memory is a powerful storage solution with respect to many types of computing, consumer electronic, and stand-alone external storage (e.g., USB drives) devices.

With respect to some flash memory types, each individual memory cell comprises a floating gate that is positioned above and isolated from a channel region of a semiconductor substrate, wherein the floating gate is positioned between the source and drain regions. Also, a control gate is provided over and isolated from the floating gate. Accordingly, the threshold voltage (Vₜₕ) of the resulting transistor is controlled by and dependent on the amount of charge retained on the floating gate. Specifically, in a switch-like manner, the minimum amount of voltage that must be applied to the control gate before the transistor is activated to permit conduction between its source and drain is determined by the level of charge retained on the floating gate. As a result, bit-value data can be programmed onto and erased from the memory cell by changing the level of charge on a floating gate in order to change the threshold voltage characteristic of the transistor.

As explained in detail below, the number of bits that can be stored in an individual memory cell is dependent upon the number of distinct voltage ranges that may be partitioned within the threshold voltage window of that memory cell. For example, to store one bit of data (referred to as a binary data), the possible threshold voltages (Vₜₕ) of the memory cell are divided into two ranges, wherein the ranges are assigned as logical data “1” and “0” respectively. A memory cell of this type of storage density may be referred to as a “single-level cell” or SLC.

By further partitioning the threshold voltage window of a memory cell into additional distinct voltage ranges, multiple levels of information may be stored. Such a memory cell may be referred to as a “multi-state cell.” For example, to store two bits of data, the threshold voltage window of a cell may be partitioned into four distinct voltage ranges (or states), wherein each range is assigned a certain bit value equal to, for example, “11,” “10,” “01,” and “00.” Accordingly, after an erase operation, the threshold voltage is negative and, therefore, may be defined as logic “11.” Therefore, the positive threshold voltages may be used for the states of “10,” “01, “00.” A memory cell of this storage density may be referred to as, for example, a “multi-level cell” or MLC. In another example, to store three bits of data, the voltage threshold window of a cell may be partitioned into eight distinct voltage ranges (or states), wherein each range is assigned a certain bit value that is equal to, for example, “111,” “110,” “100,” “010,” “011,” “000,” “001,” and “101.” A memory cell of this storage density may be referred to, for example, as a “tri-level” or “triple-level cell” (TLC). In a further example, to store four bits of data, the voltage threshold window of a cell may be partitioned into 16 distinct voltage ranges (or states), wherein each range is assigned a certain bit value that is equal to, for example, “1111,” “1110,” “1100,” “1000,” “0111,” “0011,” “0001,” “0000,” “0001,” “1001,” “1101,” “1011,” “0110,” “0100,” “0101,” and “1010.” A memory cell of this storage density may be referred to, for example, as a “quad-level cell” (QLC).

In addition to the increasing storage densities with respect to a single memory cell, advances in non-volatile memory array structures have led to memory cells being stacked in a vertical direction with respect to a semiconductor substrate, thereby creating a three-dimensional array structure as opposed to a planar two-dimensional array structure.

The specific relationship between the data that is programmed into a memory cell and the threshold voltage levels of the memory cell depends upon the specific data encoding scheme that is adopted for the memory cells.

Therefore, a memory device that comprises multi-state data (by incorporating, for example, MLC-type and/or TLC-type cells, and/or QLC-type cells) has an increased storage capacity using, for example, the same MOSFET structure and wafer size as a SLC-type cell, thereby beneficially providing a comparative cost per bit savings in such memory devices. However, as a consequence of the increased density and tightened tolerances between the partitioned voltage ranges of multi-level memory structures, programming memory operations occur at a relatively slower speed relative to single-level (SLC) memory structures because the data is being programmed to multiple target threshold voltage (Vₜₕ) ranges and also requires a higher level of precision during programming. Therefore, it would be beneficial to derive and identify technologies and methodologies that effectively increase or improve the programming speed (e.g., by allowing for concurrent programming of multiple states and/or by reducing the respective programming time (i.e., T_{prog}) of each state) in higher density memory structures, thereby boosting the efficiency of the memory device and further improving other performance parameters.

### SUMMARY

Various embodiments include a method for multi-state programming of a memory structure, the method comprising: (1) initiating a programming operation with respect to multiple program states of a non-volatile memory structure, wherein the memory structure comprises a plurality of memory elements, (2) applying, to all selected word lines of the memory structure, a programming voltage bias (V_{PGM}) level that is pre-determined to be suitable for programming a highest program state of the multiple program states, wherein the programming voltage bias (V_{PGM}) is applied according to a given program pulse width, and (3) with respect to each program state that is other than the highest program state of the multiple program states, applying a zero-volt (0V) bitline voltage bias (V_{BL}) to one or more bitlines associated with one or more of the memory elements to be programmed to the program state, wherein the zero-volt (0V) bitline voltage bias (V_{BL}) is applied according to a respective program sub-pulse width that is less than the given program pulse width. Further, according to certain embodiments, a magnitude of the respective program sub-pulse width increases an incremental amount with each higher program state. According to certain embodiments, the incremental amount is identical between each program state. Alternatively, according to certain embodiments, the incremental amount is nonidentical between each program state. Further, according to certain embodiments, the method further comprises pre-determining a magnitude of the respective program sub-pulse width such that the program state is effectively programmed according to the programming voltage bias (V_{PGM}). Further, according to certain embodiments, the multiple program states are concurrently programmed within the given program pulse width. Additionally, according to certain embodiments, the memory structure comprises a plurality of NAND-type memory cells.

Other embodiments include a memory controller comprising: (1) a communication pathway configured to couple to a non-volatile memory structure, wherein the memory structure comprises a plurality of memory elements, and (2) the memory controller is configured to: (i) initiate a programming operation with respect to multiple program states of the non-volatile memory structure, (ii) apply, to all selected word lines of the memory structure, a programming voltage bias (V_{PGM}) level that is pre-determined to be suitable for programming a highest program state of the multiple program states, wherein the programming voltage bias (V_{PGM}) is applied according to a given program pulse width, and (iii) with respect to each program state other than the highest program state of the multiple program states, apply a zero-volt (0V) bitline voltage bias (V_{BL}) to one or more bitlines associated with one or more of the memory elements selected to be programmed to the program state, wherein the zero-voltage (0V) bitline voltage bias (V_{BL}) is applied according to a respective program sub-pulse width that is less than the given program pulse width. Further, according to certain embodiments, a magnitude of the respective program sub-pulse width increases an incremental amount with each higher program state. In addition, according to certain embodiments, the incremental amount is identical between each program state. Alternatively, according to certain embodiments, the incremental amount is nonidentical between each program state. Further, according to certain embodiments, a magnitude of the respective program sub-pulse width is pre-determined such that the program state is effectively programmed according to the programming voltage bias (V_{PGM}). Additionally, according to certain embodiments, the multiple program states are concurrently programmed within the given program pulse width. In addition, according to certain embodiments, the memory structure comprises a plurality of NAND-type memory cells.

Additional embodiments include a non-volatile memory system that comprises: (1) a memory structure comprising a population of NAND-type memory elements, and (2) a memory controller that is coupled to the memory structure, the memory controller: (i) initiating a programming operation with respect to multiple program states of the memory structure, (ii) applying, to all selected word lines of the memory structure, a programming voltage bias (V_{PGM}) level pre-determined to be suitable for programming a highest program state of the multiple program states, wherein the programming voltage bias is applied according to a given program pulse width, and (iii) with respect to each program state that is other than the highest program state of the multiple program states, applying a zero-volt (0V) bitline voltage bias (V_{BL}) to one or more bitlines associated with one or more of the memory elements selected to be programmed to the program state, wherein the zero-volt (0V) bitline voltage bias (V_{BL}) is applied according to a respective program sub-pulse width that is less than the given program pulse width. Further, according to certain embodiments, a magnitude of the respective program sub-pulse width increases an incremental amount with each higher program state. Additionally, according to certain embodiments, the incremental amount is identical between each of the program states. Alternatively, according to certain other embodiments, the incremental amount is identical between each of the program states. Furthermore, according to certain embodiments, a magnitude of the respective program sub-pulse width is pre-determined such that the program state is effectively programmed according to the programming voltage bias (V_{PGM}). Additionally, according to certain embodiments, the multiple program states are concurrently programmed within the given program pulse width.

### BRIEF DESCRIPTION OF THE DRAWINGS

A more detailed description is set forth below with reference to example embodiments depicted in the appended figures. Understanding that these figures depict only example embodiments of the disclosure and are, therefore, not to be considered limiting of its scope, the disclosure is described and explained with added specificity and detail through the use of the accompanying drawings in which:

FIG. 1 is a block diagram of a memory system, in accordance with exemplary embodiments;

FIG. 2 is a schematic depiction of a non-volatile memory cell, in accordance with exemplary embodiments;

FIG. 3 depicts the relationship between a source-drain current I_{D} and a control gate voltage V_{CG} for four different charges Q1-Q4 that a floating gate of a non-volatile memory cell may be selectively storing at any one time and at a fixed drain voltage, in accordance with exemplary embodiments;

FIG. 4A schematically depicts a series of NAND-type memory cells that are organized into a string, in accordance with exemplary embodiments;

FIG. 4B schematically depicts an array of memory cells, comprising a plurality of NAND-type strings, such as the type depicted in FIG. 4A, in accordance with exemplary embodiments;

FIG. 5 depicts a page of memory cells being sensed or programmed in parallel, and in relation to a memory array organized in the NAND-type configuration, in accordance with exemplary embodiments;

FIGS. 6A-6C depict stages of programming four states of a population of MLC NAND-type memory cells, in accordance with exemplary embodiments;

FIGS. 7A-7C depict stages of programming eight states of a population of TLC NAND-type memory cells, in accordance with exemplary embodiments;

FIGS. 8A-8C depict stages of programming 16 states of a population of QLC NAND-type memory cells, in accordance with exemplary embodiments;

FIG. 9 depicts a vertical NAND-type string in accordance with an exemplary embodiment;

FIG. 10 is a perspective view of a representative subsection of a monolithic three-dimensional NAND-type memory array, in accordance with exemplary embodiments;

FIG. 11 schematically depicts a configuration of a non-volatile memory array that is accessible by read/write circuits via row and column decoders, in accordance with exemplary embodiments;

FIG. 12 is a block diagram of an individual read/write module, in accordance with an exemplary embodiment;

FIG. 13A schematically depicts a memory device with a bank of partitioned read/write stacks, in accordance with exemplary embodiments;

FIG. 13B schematically depicts the memory device of FIG. 13A in a slightly different configuration, in accordance with exemplary embodiments;

FIG. 14 schematically depicts various components of a read/write stack, such as the read/write stacks depicted in FIG. 13A, in accordance with exemplary embodiments;

FIG. 15A schematically depicts a plurality of read/write stacks arranged amongst read/write circuits of a memory device, such as the memory device depicted in FIG. 13A, in accordance with exemplary embodiments;

FIG. 15B is a block diagram depicting a sense block of a read/write stack, such as the read/write stacks depicted in FIG. 13A, in accordance with exemplary embodiments;

FIG. 16A is a plot diagram depicting a threshold voltage (Vth) distribution of programmed states of a population of QLC NAND-type memory cells, in accordance with an exemplary embodiment of a “serial”-type programming operation;

FIG. 16B is a graphical chart indicating a total number of program loops required to complete the programming operation depicted in FIG. 16A, in accordance with exemplary embodiments;

FIG. 17A is a “lookup” table or chart indicating, for each program state (i.e., State “1” through State “15”) of a population of QLC NAND-type memory cells, a respective: (1) programming voltage bias, (2) bitline voltage bias, and (3) “effective” programming voltage bias as applied in accordance with an exemplary embodiment of a “concurrent”-type programming operation;

FIG. 17B is a bar graph illustrating, for each program state, the relationship or the dependency between the programming voltage bias, bitline voltage bias, and “effective” programming voltage bias delineated in the table of FIG. 17A, in accordance with exemplary embodiments;

FIG. 17C is a graphical chart indicating a total number of program loops required to complete the programming operation depicted in FIGS. 17A and 17B, in accordance with exemplary embodiments;

FIG. 17D is a signal timing diagram in accordance with the programming operation depicted in FIGS. 17A and 17B, in accordance with exemplary embodiments;

FIG. 17E is a flow diagram generally illustrating several steps of the programming operation depicted in FIGS. 17A and 17B, in accordance with exemplary embodiments;

FIG. 18A is a “lookup” table or chart indicating, for each program state (i.e., State “1” through State “15”) of a population of QLC NAND-type memory cells, a respective: (1) programming voltage bias, (2) bitline voltage bias, and (3) “effective” programming voltage bias as applied in accordance with an exemplary embodiment of a “bifurcated concurrent”-type programming operation;

FIG. 18B is a bar graph illustrating, for each program state, the relationship or the dependency between the programming voltage bias, bitline voltage bias, and “effective” programming voltage bias delineated in the table of FIG. 18A, in accordance with exemplary embodiments;

FIG. 18C is a graphical chart indicating a total number of program loops required to complete the programming operation depicted in FIGS. 18A and 18B, in accordance with exemplary embodiments;

FIG. 18D is a signal timing diagram in accordance with the programming operation depicted in FIGS. 18A and 18B, in accordance with exemplary embodiments;

FIG. 18E is a flow diagram generally illustrating several steps of the programming operation depicted in FIGS. 18A and 18B, in accordance with exemplary embodiments;

FIG. 19A is a “lookup” table or chart indicating, for each program state (i.e., State “1” through State “15”) of a population of QLC NAND-type memory cells, a respective: (1) program “sub-pulse” width, and (2) bitline voltage bias, as applied in accordance with an exemplary embodiment of a “bitline timing based concurrent”-type programming operation;

FIG. 19B is a graphical chart indicating a total number of program loops required to complete the programming operation depicted in FIG. 19A, in accordance with exemplary embodiments;

FIG. 19C is a signal timing diagram in accordance with the programming operation depicted in FIG. 19A, in accordance with exemplary embodiments;

FIG. 19D is a flow diagram generally illustrating several steps of the programming operation depicted in FIGS. 19A and 19C, in accordance with exemplary embodiments;

FIG. 20A is a “lookup” table or chart indicating, for each program state (i.e., State “1” through State “15”) of a population of QLC NAND-type memory cells, a respective: (1) program “sub-pulse” width, and (2) bitline voltage bias, as applied in accordance with an exemplary embodiment of a “bifurcated bitline timing based concurrent”-type programming operation; and

FIG. 20B is a signal timing diagram in accordance with the programming operation depicted in FIG. 20A, in accordance with exemplary embodiments.

### DETAILED DESCRIPTION

The following description is directed to various exemplary embodiments of the disclosure. Although one or more of these embodiments may be preferred, the embodiments disclosed should not be interpreted, or otherwise used, as limiting the scope of the disclosure, including the claims. In addition, one skilled in the art will understand that the following description has broad application, and the detailed explanation of any specific embodiment is meant only to be exemplary of that embodiment and is not intended to suggest that the scope of the disclosure, including the claims, is limited to that particular embodiment.

The several aspects of the present disclosure may be embodied in the form of an apparatus, system, method, or computer program process. Therefore, aspects of the present disclosure may be entirely in the form of a hardware embodiment or a software embodiment (including but not limited to firmware, resident software, micro-code, or the like), or may be a combination of both hardware and software components that may generally be referred to collectively as a “circuit,” “module,” “apparatus,” or “system.” Further, various aspects of the present disclosure may be in the form of a computer program process that is embodied, for example, in one or more non-transitory computer-readable storage media storing computer-readable and/or executable program code.

Additionally, various terms are used herein to refer to particular system components. Different companies may refer to a same or similar component by different names and this description does not intend to distinguish between components that differ in name but not in function. To the extent that various functional units described in the following disclosure are referred to as “modules,” such a characterization is intended to not unduly restrict the range of potential implementation mechanisms. For example, a “module” could be implemented as a hardware circuit that comprises customized very-large-scale integration (VLSI) circuits or gate arrays, or off-the-shelf semiconductors that include logic chips, transistors, or other discrete components. In a further example, a module may also be implemented in a programmable hardware device such as a field programmable gate array (FPGA), programmable array logic, a programmable logic device, or the like. Furthermore, a module may also, at least in part, be implemented by software executed by various types of processors. For example, a module may comprise a segment of executable code constituting one or more physical or logical blocks of computer instructions that translate into an object, process, or function. Also, it is not required that the executable portions of such a module be physically located together, but rather, may comprise disparate instructions that are stored in different locations and which, when executed together, comprise the identified module and achieve the stated purpose of that module. The executable code may comprise just a single instruction or a set of multiple instructions, as well as be distributed over different code segments, or among different programs, or across several memory devices, etc. In a software, or partial software, module implementation, the software portions may be stored on one or more computer-readable and/or executable storage media that include, but are not limited to, an electronic, magnetic, optical, electromagnetic, infrared, or semiconductor-based system, apparatus, or device, or any suitable combination thereof. In general, for purposes of the present disclosure, a computer-readable and/or executable storage medium may be comprised of any tangible and/or non-transitory medium that is capable of containing and/or storing a program for use by or in connection with an instruction execution system, apparatus, processor, or device.

Similarly, for the purposes of the present disclosure, the term “component” may be comprised of any tangible, physical, and non-transitory device. For example, a component may be in the form of a hardware logic circuit that is comprised of customized VLSI circuits, gate arrays, or other integrated circuits, or is comprised of off-the-shelf semiconductors that include logic chips, transistors, or other discrete components, or any other suitable mechanical and/or electronic devices. In addition, a component could also be implemented in programmable hardware devices such as field programmable gate arrays (FPGA), programmable array logic, programmable logic devices, etc. Furthermore, a component may be comprised of one or more silicon-based integrated circuit devices, such as chips, die, die planes, and packages, or other discrete electrical devices, in an electrical communication configuration with one or more other components via electrical conductors of, for example, a printed circuit board (PCB) or the like. Accordingly, a module, as defined above, may in certain embodiments, be embodied by or implemented as a component and, in some instances, the terms module and component may be used interchangeably.

Where the term “circuit” is used herein, it comprises one or more electrical and/or electronic components that constitute one or more conductive pathways that allow for electrical current to flow. A circuit may be in the form of a closed-loop configuration or an open-loop configuration. In a closed-loop configuration, the circuit components may provide a return pathway for the electrical current. By contrast, in an open-looped configuration, the circuit components therein may still be regarded as forming a circuit despite not including a return pathway for the electrical current. For example, an integrated circuit is referred to as a circuit irrespective of whether the integrated circuit is coupled to ground (as a return pathway for the electrical current) or not. In certain exemplary embodiments, a circuit may comprise a set of integrated circuits, a sole integrated circuit, or a portion of an integrated circuit. For example, a circuit may include customized VLSI circuits, gate arrays, logic circuits, and/or other forms of integrated circuits, as well as may include off-the-shelf semiconductors such as logic chips, transistors, or other discrete devices. In a further example, a circuit may comprise one or more silicon-based integrated circuit devices, such as chips, die, die planes, and packages, or other discrete electrical devices, in an electrical communication configuration with one or more other components via electrical conductors of, for example, a printed circuit board (PCB). A circuit could also be implemented as a synthesized circuit with respect to a programmable hardware device such as a field programmable gate array (FPGA), programmable array logic, and/or programmable logic devices, etc. In other exemplary embodiments, a circuit may comprise a network of non-integrated electrical and/or electronic components (with or without integrated circuit devices). Accordingly, a module, as defined above, may in certain embodiments, be embodied by or implemented as a circuit.

It will be appreciated that example embodiments that are disclosed herein may be comprised of one or more microprocessors and particular stored computer program instructions that control the one or more microprocessors to implement, in conjunction with certain non-processor circuits and other elements, some, most, or all of the functions disclosed herein. Alternatively, some or all functions could be implemented by a state machine that has no stored program instructions, or in one or more application-specific integrated circuits (ASICs) or field-programmable gate arrays (FPGAs), in which each function or some combinations of certain of the functions are implemented as custom logic. A combination of these approaches may also be used. Thus, methods and means for these functions are described herein. Further, references below to a “controller” shall be defined as comprising individual circuit components, an application-specific integrated circuit (ASIC), a microcontroller with controlling software, a digital signal processor (DSP), a field programmable gate array (FPGA), and/or a processor with controlling software, or combinations thereof.

Further, the terms “program,” “software,” “software application,” and the like as used herein, refer to a sequence of instructions designed for execution on a computer-implemented system. Accordingly, a “program,” “software,” “application,” “computer program,” or “software application” may include a subroutine, a function, a procedure, an object method, an object implementation, an executable application, an applet, a servlet, a source code, an object code, a shared library/dynamic load library and/or other sequence of specific instructions designed for execution on a computer system.

Additionally, the terms “couple,” “coupled,” or “couples,” where used herein, are intended to mean either a direct or an indirect connection. Thus, if a first device couples, or is coupled to, a second device, that connection may be by way of a direct connection or through an indirect connection via other devices (or components) and connections.

Regarding the use herein of terms such as “an embodiment,” “one embodiment,” an “exemplary embodiment,” a “particular embodiment,” or other similar terminology, these terms are intended to indicate that a specific feature, structure, function, operation, or characteristic described in connection with the embodiment is found in at least one embodiment of the present disclosure. Therefore, the appearances of phrases such as “in one embodiment,” “in an embodiment,” “in an exemplary embodiment,” etc., may, but do not necessarily, all refer to the same embodiment, but rather, mean “one or more but not all embodiments” unless expressly specified otherwise. Further, the terms “comprising,” “having,” “including,” and variations thereof, are used in an open-ended manner and, therefore, should be interpreted to mean “including, but not limited to . . . ” unless expressly specified otherwise. Also, an element that is preceded by “comprises . . . a” does not, without more constraints, preclude the existence of additional identical elements in the subject process, method, system, article, or apparatus that comprises the element.

The terms “a,” “an,” and “the” also refer to “one or more” unless expressly specified otherwise. In addition, the phrase “at least one of A and B” as may be used herein and/or in the following claims, whereby A and B are variables indicating a particular object or attribute, indicates a choice of A or B, or both A and B, similar to the phrase “and/or.” Where more than two variables are present in such a phrase, this phrase is hereby defined as including only one of the variables, any one of the variables, any combination (or sub-combination) of any of the variables, and all of the variables.

Further, where used herein, the term “about” or “approximately” applies to all numeric values, whether or not explicitly indicated. These terms generally refer to a range of numeric values that one of skill in the art would consider equivalent to the recited values (e.g., having the same function or result). In certain instances, these terms may include numeric values that are rounded to the nearest significant figure.

In addition, any enumerated listing of items that is set forth herein does not imply that any or all of the items listed are mutually exclusive and/or mutually inclusive of one another, unless expressly specified otherwise. Further, the term “set,” as used herein, shall be interpreted to mean “one or more,” and in the case of “sets,” shall be interpreted to mean multiples of (or a plurality of) “one or mores,” “ones or more,” and/or “ones or mores” according to set theory, unless expressly specified otherwise.

Various elements of the present disclosure are described below with reference to schematic flowchart diagrams and/or schematic block diagrams depicting methods, apparatuses, systems, and computer program processes according to exemplary embodiments of the present disclosure, wherein each block, or combinations of blocks, of the schematic flowchart and/or schematic block diagrams, can be implemented by specifically-written computer program instructions. As is understood in the art, the computer program instructions are executed by a designated processor of a computer or other programmable data processing apparatus, thereby creating the mechanisms for implementing the functions, acts, and/or operations specifically set forth in the one or more blocks of the schematic flowchart and/or schematic block diagrams. Further, it is noted that, in certain alternative process implementations, the functions specified in a block may occur out of the precise order depicted in the schematic flowchart and/or block diagrams. For example, two blocks depicted in the diagram as occurring in succession may, in fact, be executed substantially at the same time (i.e., concurrently), or even executed in a reverse order, depending upon the functionality involved. In addition, other process steps and methods that are equivalent in function, logic, or effect to one or more blocks, or portions thereof, of the diagrams may be conceived and are contemplated as being within the scope of the present disclosure. Furthermore, although the schematic diagrams may depict various arrow types and directions and line types as a matter of illustration, they are not intended to limit the scope of corresponding embodiments. For instance, an arrow may represent or signify a waiting or monitoring period of unspecified duration between enumerated steps of the depicted exemplary embodiment.

In the detailed description that follows, reference is made to the appended drawings, which form a part thereof. It is recognized that the foregoing summary is illustrative only and is not intended to be limiting in any manner. In addition to the illustrative aspects, example embodiments, and features described above, additional aspects, exemplary embodiments, and features will become apparent by reference to the drawings and the detailed description below. The description of elements in each figure may refer to elements of proceeding figures. Like reference numerals may refer to like elements in the figures, including alternate exemplary embodiments of like elements.

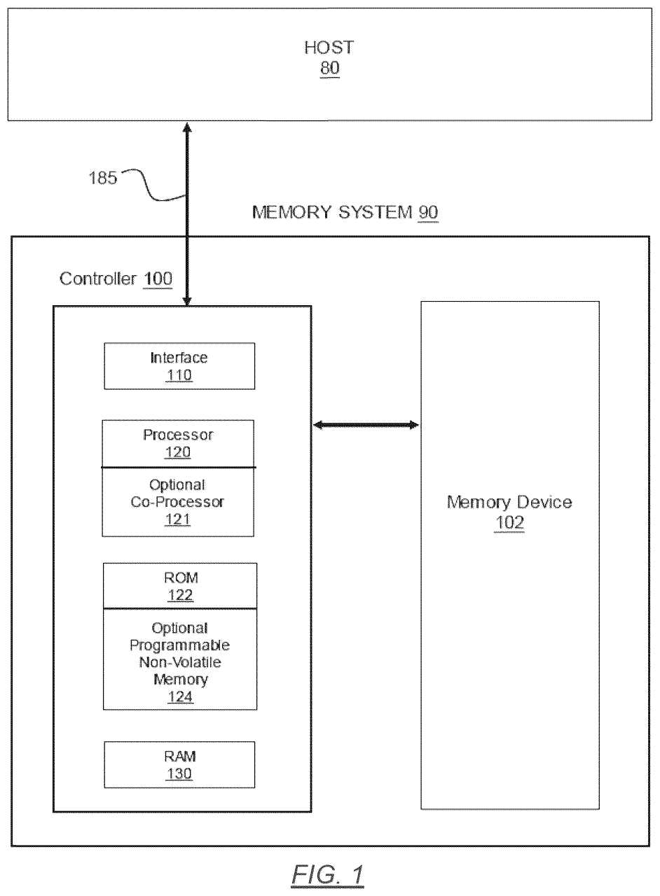

Referring now to the drawings in detail and beginning with FIG. 1, there is depicted an exemplary embodiment of a memory system 90 and is an illustration of its main hardware components. In this particular embodiment, the memory system 90 operates and is in communication with a host device 80 through a host interface. Further, the memory system 90 comprises a memory device 102 whose operations are controlled by a controller 100. The host device 80 may comprise any device or system that utilizes the memory system 90 (e.g., a computing device). Accordingly, the memory system 90 may be in the form of a removable memory card or an embedded memory system. For example, the memory system 90 may be embedded in a solid-state drive that is installed in a laptop computer. In another example, the memory system 90 may be embedded within the host device 80 such that the host 80 and the memory system 90 (including controller 100) are formed on a single integrated circuit chip. In embodiments in which the memory system 90 is implemented within a memory card, the host device 80 may include a built-in receptacle for the one or more types of memory cards or flash drives (e.g., a universal serial bus (USB) port, or a memory card slot). Further, the host 80 may use adapters in which a memory card is plugged.

Still referring to FIG. 1, as described in detail below, the memory device 102 may comprise one or more memory arrays of a plurality of non-volatile memory cells that are distributed over one or more integrated circuit chips. And, in accordance with this particular embodiment, the controller 100 may include several components that may include, but are not limited to, interface circuits 110, a processor 120, ROM (read-only memory) 122, RAM (random access memory) 130, programmable non-volatile memory 124, and additional components. The controller 100 may, for example, be in the form of one or more application-specific integrated circuits (ASIC) in which the components included in such an ASIC generally depend on the particular application.

With respect to the memory device 102 itself, FIG. 2 is a schematic depiction of an individual non-volatile memory cell 10 in accordance with an exemplary embodiment. As is mentioned above, the memory cell 10 may be implemented by a field-effect transistor having a charge storage unit 20, such as a floating gate or a dielectric layer. In addition, the memory cell 10 comprises a source region 14 and a drain region 16. Further, a control gate 30 is positioned above the floating gate 20. Example types of non-volatile memory cells having this general structure include, but are not limited to, electrically erasable programmable read-only memory (EEPROM) and flash EEPROM, NAND (NOT-AND)-type cells, and memory devices utilizing dielectric storage elements (e.g., NROM™). In operation, the memory state of a cell (e.g., programmed or erased) may, in accordance with certain embodiments, be read by sensing the conduction current across the source and drain electrodes of the memory cell when a reference voltage is applied to the control gate 30. More specifically, for each given charge on the floating gate 20 of a memory cell, a corresponding conduction current with respect to a fixed reference control gate voltage may be detected. Accordingly, as is described above, the range of charges programmable onto the floating gate defines a corresponding threshold voltage window or a corresponding conduction current window of the memory cell 10. Alternatively, rather than detecting the conduction current among a partitioned current window, it is possible to set the threshold voltage for a given memory state under test at the control gate 30 and detect if the resulting conduction current is higher than or lower than a threshold current (i.e., a cell-read reference current). In one such exemplary implementation, detection of the conduction current relative to a threshold current is accomplished by examining a discharge rate of the conduction current through the capacitance of the bit line.

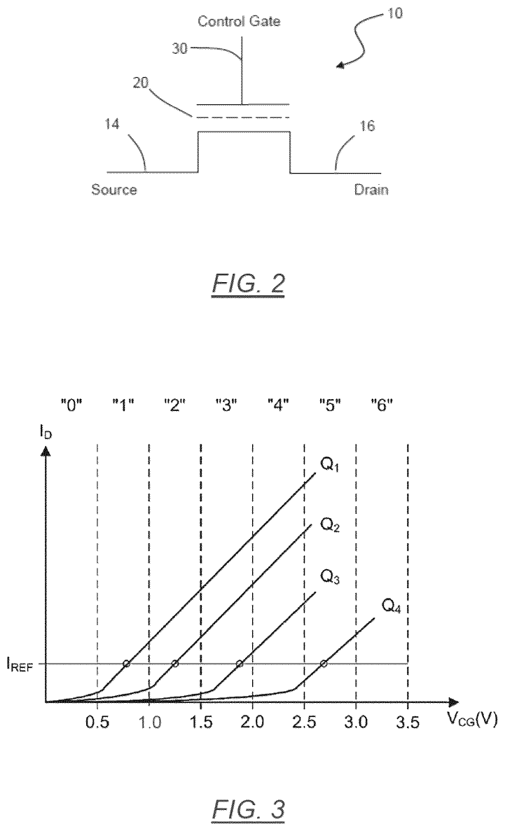

FIG. 3 provides a graphical illustration of the correlation between the source-drain current I_{D} and control gate voltage V_{CG} for, for example, a non-volatile memory cell 10 having four different charge states Q1-Q4 that the floating gate may be selectively storing at any given time. As shown, with a fixed drain voltage bias, there exists four solid I_{D} versus V_{CG} curves representing four charge levels that can be programmed on a floating gate of the memory cell, wherein the four charge levels respectively correspond to four of eight possible memory states. Therefore, as an example, the threshold voltage window of a population of memory cells may range from 0.5 V to 3.5 V. In such an example, seven programmed memory states assigned as “0,” “1,” “2,” “3,” “4,” “5,” “6,” respectively, and one erased state (which is not shown in FIG. 3), may be demarcated by partitioning the threshold window into regions at intervals of 0.5 V each. Accordingly, if a reference current, I_{REF}, of 2 μA is used as shown, then a cell programmed with Q1 voltage may be considered to be in a memory state “1” as its curve intersects with I_{REF} in the region of the threshold window that is demarcated by the voltage range V_{CG}=0.5 V and 1.0 V. Similarly, Q4 is in a memory state “5.”

Thus, as mentioned above, the more states that a memory cell 10 is made to store, the more finely divided is its threshold voltage window. For example, in a memory cell 10 that has a threshold voltage window ranging from −1.5 V to 5 V, thereby providing a possible maximum width of 6.5 V, and is to store 16 memory states, each state may only occupy a voltage range of from 200 mV to 300 mV. Such a narrow voltage range will require higher precision in programming and reading operations in order to achieve the required resolution.

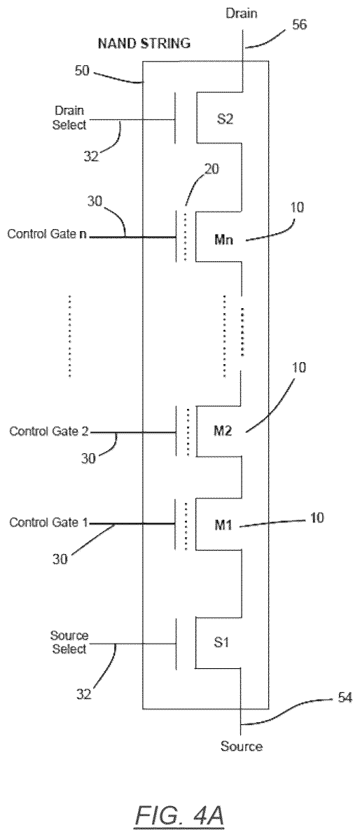

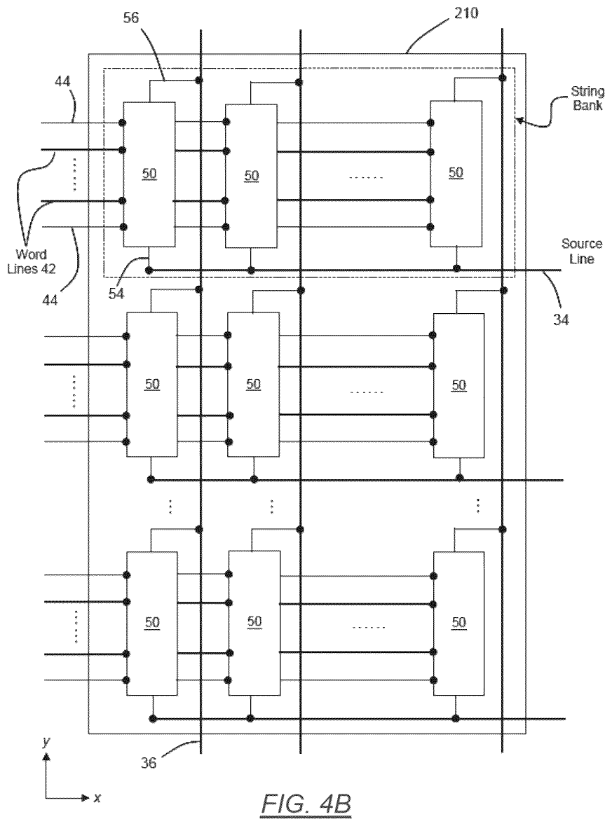

Individual memory cells 10 are organized into strings in which the memory cells are placed in series. For example, depicted in FIG. 4A is an exemplary embodiment of a string 50 comprising NAND-type memory cells in which the series of the cells' respective transistor elements M1, M2, . . . , Mn (wherein “n” may equal 4, 8, 16 or higher) are daisy-chained with respect to their sources and drains. Further, as discussed with respect to FIG. 3, each memory transistor 10 in the string 50 has a charge storage element 20 (e.g., a floating gate) for storing a certain amount of charge so as to represent an intended memory state of that cell. And, as explained in greater detail below, each memory transistor 10 comprises a control gate 30 that allows control over the read and write operations. Present at the source terminal 54 and drain terminal 56 of the string 50 are select transistors S1, S2 that control the transistor elements' connection to the outlying memory array. Specifically, when the source select transistor S1 is turned on, the source terminal 54 is coupled to a source line. Likewise, when the drain select transistor S2 is turned on, the drain terminal 56 is coupled to a bit line of the memory array.

Expanding outward a hierarchical level, FIG. 4B is a schematic diagram depicting an exemplary embodiment of a memory array 210 comprised of a plurality of NAND strings 50 of the type illustrated in FIG. 4A. Along each column of NAND strings 50, a bit line 36 is coupled to the drain terminal 56 of each NAND string. In addition, along each bank of NAND strings 50, a source line 34 is coupled to the source terminals 54 of each NAND string. Further, the control gates 30 of the memory transistors 10 in a row of memory cells in the bank of NAND strings 50 are connected to the same word line 42. Accordingly, when an addressed memory transistor 10 within a NAND string 50 is read or verified during a programming operation, an appropriate voltage is applied to its control gate 30. Concurrently, the remaining non-addressed memory transistors 10 within the NAND string 50 are fully turned on by applying a sufficient voltage to their respective control gates 30. As a result, a conductive pathway is created from the source of the addressed memory transistor 10 to the source terminal 54 of NAND string 50, and from the drain of the addressed memory transistor 10 to the drain terminal 56 of the cell.

Further, the control gates 32 of the select transistors S1, S2 of each NAND string 50 in the memory array 210 provide control access to the NAND string at its source terminal 54 and drain terminal 56. The control gates 32 of the select transistors S1, S2 along a row in a bank of NAND strings 50 are connected to the same select line 44. Thus, an entire row of memory cells 10 in a bank of NAND strings 50 can be addressed by applying the appropriate voltages on the word lines 42 and select lines 44 of the bank of NAND strings 50.

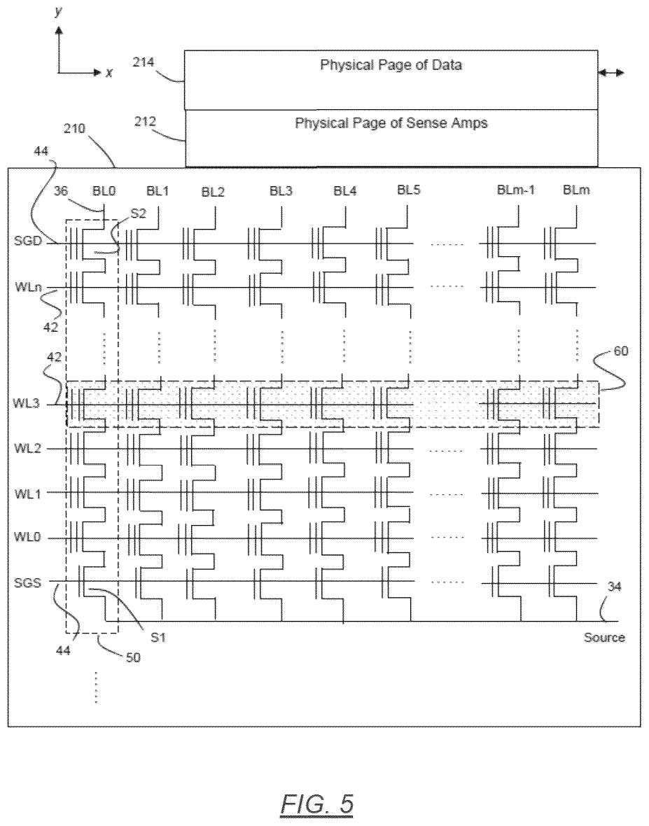

Turning now to FIG. 5, there is depicted a detailed illustration of one bank of NAND strings 50 of a memory array 210 according to an exemplary embodiment thereof. This view is particularly useful in visualizing a row-by-row configuration of the memory array 210, wherein each row of the array 210 may be referred to as a “page.” Accordingly, a physical page (such as page 60 denoted in FIG. 5) is a group of memory cells 10 that is enabled to be sensed or programmed in parallel. In fact, a page is the smallest unit of the memory device that may be programmed or written to. Programming of a page is accomplished by a corresponding page of sense amplifiers 212, wherein each sense amplifier may be coupled to a respective NAND string 50 via a bit line (e.g., see respective bit lines BL0, BL1, BL2, BL3, BL4, BL5, . . . , BLm-1, and BLm illustrated in FIG. 5). Thus, a page 60 is enabled by the control gates of the plurality of memory cells 10 in page 60, which are connected to a common word line 42, and each memory cell 10 of the page 60 is accessible by a sense amplifier via a bit line 36. Therefore, when programming or sensing a page 60 of memory cells 10, a programming or sensing voltage is respectively applied to the common word line (e.g., word line WL3 with respect to the page 60) together with appropriate voltages on the bit lines.

Regarding the manner in which data is programmed and erased, it is important to note that, with respect to flash memory, a memory cell must be programmed from an erased state. In other words, a floating gate 20 must first be emptied of charge, thereby placing the memory cell in an erased state, before a programming operation can subsequently add a desired amount of charge back to the floating gate 20. Thus, the level of charge on a floating gate 20 cannot be incrementally increased or decreased from its previous programmed level. Therefore, it is not possible for update data to overwrite the existing data of a memory cell 10. Rather, the update data must be programmed to a previous unwritten location.

For purposes of promoting performance in erase operations, an array 210 of memory cells 10 is, for example, divided into a large number of blocks of memory cells, wherein a block is the smallest unit of the memory device in which the memory cells contained may be erased together. Furthermore, each block of memory cells 10 may be divided into a number of physical pages 60 wherein, as mentioned above, a programming operation is conducted page by page. Accordingly, a logical page is a unit of programming or reading that contains a number of bits equal to the number of memory cells 10 in a given physical page. For example, in a memory device of the SLC-type in which one bit of data is stored in each memory cell 10, one physical page 60 stores one logical page of data. Accordingly, in a memory device of the MLC-type in which two bits of data are stored in each memory cell 10, one physical page 60 can store two logical pages of data. As such, one or more logical pages of data are typically stored in one row (i.e., page 60) of memory cells. A page 60 can store one or more sectors wherein a sector is comprised of both user data and overhead data. In an exemplary embodiment, individual pages 60 may be divided into segments in which each segment contains the fewest number of memory cells 10 that may be written at one time in a basic programming operation.

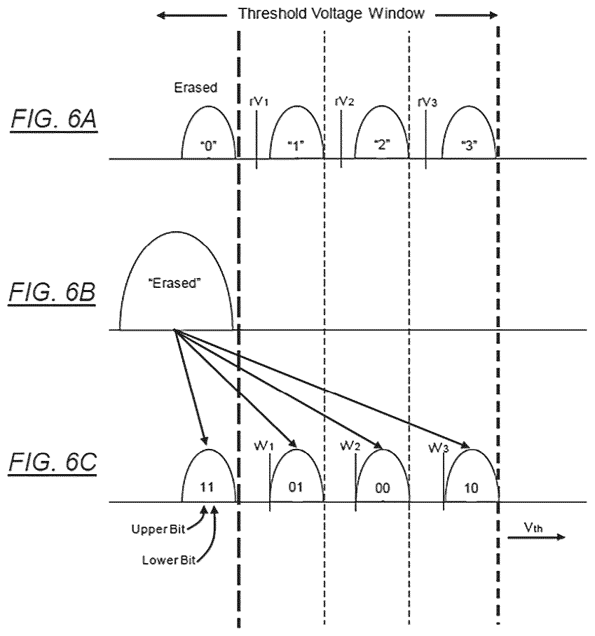

To illustrate an exemplary embodiment of the programming stages of a MLC-type memory device comprising a population of four-state memory cells, reference is made to FIGS. 6A-6C. In FIG. 6A, there is depicted a population of memory cells in which the characteristic threshold voltage window is divided into four distinct voltage distributions wherein each distribution corresponds to a programmable memory state (i.e., memory states “0,” “1,” “2,” and “3”). FIG. 6B illustrates an initial distribution of “erased” threshold voltages for an erased memory. In FIG. 6C, much of the memory cell population is programmed such that the initial “erased” threshold voltage of a given memory cell 10 is moved to a higher value into one of the three divided voltage zones demarcated by verify levels vV1, vV2, and vV3. Accordingly, each memory cell can be programmed to one of the three programmable states “1,” “2,” and “3,” or remain in the “erased” state. On a bit level, a 2-bit code having a lower bit and an upper bit can be used to represent each of the four memory states. For example, as depicted in FIG. 6C, the memory states “0,” “1,” “2,” and “3” may be assigned bit values “11,” “01,” “00,” and “10” respectively. In such an example, the 2-bit data may be read from the memory by sensing in a “full-sequence” mode where the two bits are sensed together by sensing relative to the corresponding read demarcation threshold voltages rV1, rV2, and rV3 in three sub-passes respectively.

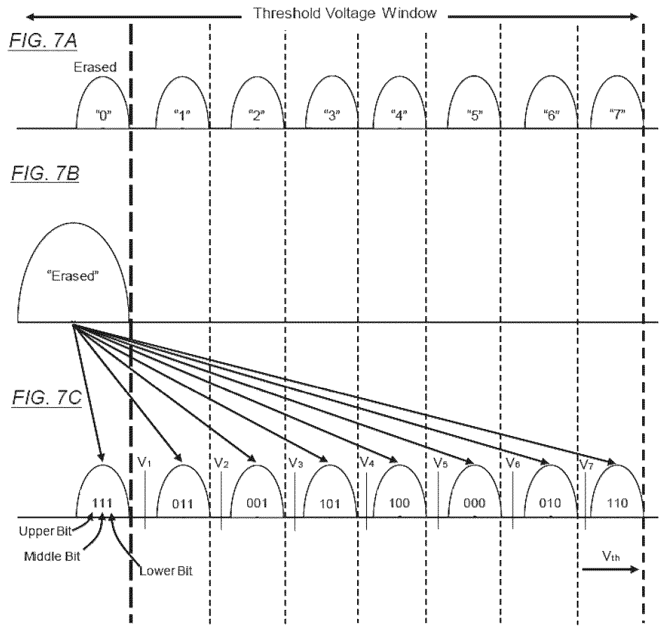

Similarly, FIGS. 7A-7C illustrate programming stages of a TLC-type memory device comprising a population of eight-state memory cells, each cell being programmable into eight distinct distributions of threshold voltages that, in accordance with this particular embodiment, represent memory states “0,” “1,” “2,” “3,” “4,” “5,” “6,” and “7,” respectively (as shown in FIG. 7A). Thus, FIG. 7B depicts an initial distribution of “erased” threshold voltages for an erased memory. Further, FIG. 7C depicts an example of the memory after many of the memory cells have been programmed. As a result, a cell's threshold voltage is moved higher into one of the distinct voltage ranges demarcated by levels V1, V2, V3, V4, V5, V6, and V7. Accordingly, each memory cell can be programmed to one of the seven programmed states “1” through “7,” or can remain unprogrammed in the “erased” state. As a consequence of the programming, the initial distribution of the “erased” state as shown in FIG. 7B becomes narrower as indicated by the “0” state in FIG. 7C. In this case, a 3-bit code having lower, middle, and upper bits can be used to represent each of the memory states (i.e., “111,” “011,” “001,” “101,” “100,” “000,” “010,” and “110”) and the 3-bit data may also be read from the memory by sensing in the “full-sequence” mode where the three bits are sensed together by sensing relative to the demarcation threshold values V1 through V7 in seven sub-passes respectively.

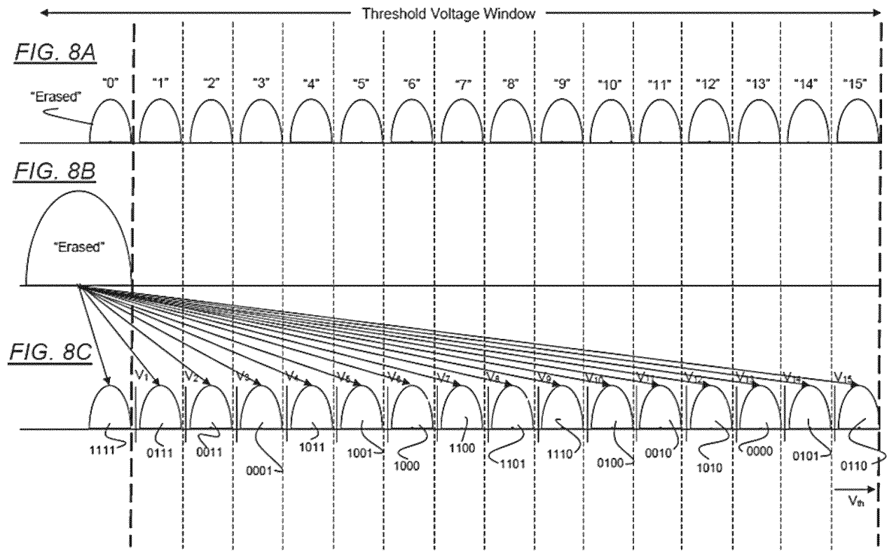

Continuing in a similar manner, FIGS. 8A-8C illustrate the programming stages of a QLC-type memory device comprising a population of 16-state memory cells, each cell being programmable into 16 distinct distributions of threshold voltages that, in accordance with this particular embodiment, represent memory states “0,” “1,” “2,” “3,” “4,” “5,” “6,” “7,” “8,” “9,” “10,” “11,” “12,” “13,” “14,” and “15,” respectively (as shown in FIG. 8A). Accordingly, FIG. 8B depicts an initial distribution of “erased” threshold voltages for an erased memory; whereas FIG. 8C depicts an example of the memory after programming. As depicted, a cell's threshold voltage is moved higher into one of the distinct voltage ranges, as demarcated by levels V1, V2, V3, V4, V5, V6, V7, V8, V9, V10, V11, V12, V13, V14, and V15. Therefore, each memory cell can be programmed to one of 15 programmed states “1” through “15,” or can remain unprogrammed in the “erased” state. Again, as a consequence of the programming, the initial distribution of the “erased” state as shown in FIG. 8B becomes narrower as indicated by the “0” state in FIG. 8C. Thus, according to this particular distribution, a 4-bit code having lower, middle, upper and top bits can be used to represent each of the memory states (i.e., “1111,” “1110,” “1100,” “1101,” “0101,” “0100,” “0000,” “0010,” “0110,” “0111,” “0011,” “0001,” “1001,” “1011,” “1010,” and “1000”).

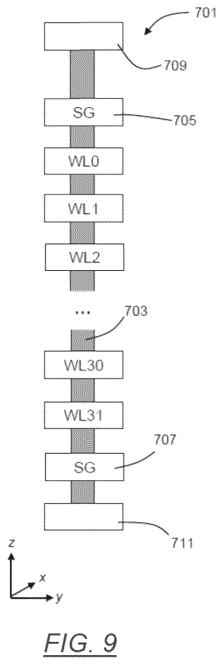

In FIGS. 4A-4B and 5 and the foregoing corresponding discussion, there is generally described a two-dimensional (or planar) memory array 210 (lying in a x-y plane, for example), which may comprise NAND-type memory cells. However, in an alternative configuration, a memory array may be in the form of a three-dimensional array that, unlike being formed on a planar surface of a semiconductor wafer, the array extends upwards from the wafer surface and comprises stacks or columns of memory cells extending vertically in an upwards direction (for example, in a z direction that is perpendicular to the x-y plane). For example, in FIG. 9 there is depicted an exemplary embodiment of a NAND-type string 701, which is operated in a similar manner as a planar two-dimensional NAND-type string (such as the NAND-type string 50 described above). In this configuration, a memory cell is formed at the juncture of a vertical bit line (see e.g., local bit line 703) and a word line (see e.g., word lines WL0, WL1, etc.), wherein a charge trapping layer located between the local bit line 703 and an intersecting word line stores charge (which dictates the threshold voltage of the transistor formed by the word line—gate—coupled to the vertical bit line—channel—that it encircles). To form such a vertical string 701, stacks of word lines are formed and memory holes are etched at the appropriate locations where cells are to be formed, wherein each memory hole is lined with a charge trapping layer and filled with a suitable local bit line/channel material. Dielectric layers are included for the necessary isolation. Further, located at either end of the NAND-type string 701 are select gates 705, 707, which allow for the selective connection to, or isolation from, external elements 709, 711 that include, for example, conductive lines such as common source lines or bit lines that serve large numbers of strings 701 of an array. In the particular embodiment shown in FIG. 9, the vertical NAND-type string 701 has 32 memory cells (i.e., at the juncture between local bit line 703 and word lines 0 through 31) connected in series. However, a NAND-type string 701 may comprise any suitable number of memory cells.

As described above, memory cells of the memory structure 200 may be arranged in a single memory device level in an ordered two-dimensional array of a plurality of rows and/or columns. Alternatively, a three-dimensional memory array may be arranged such that memory cells occupy multiple planes or multiple memory device levels, thereby forming a structure that has three dimensions (e.g., in the x, y, and z directions, wherein the z direction is substantially perpendicular and the x and y directions are substantially parallel to the major surface of the semiconductor substrate). In some exemplary embodiments, a three-dimensional memory structure 200 may be vertically arranged as a stack of multiple two-dimensional memory array device levels. In other exemplary embodiments, the three-dimensional memory structure 200 is arranged as multiple vertical columns (wherein each column extends substantially perpendicular to the major surface of the substrate, i.e., in the z direction) with each column having multiple memory cells. In this example, the vertical columns may be arranged in a two-dimensional configuration (i.e., in the x-y plane), thereby forming a three-dimensional arrangement in which the memory cells are on multiple vertically stacked memory planes. Other configurations of memory elements in three dimensions can also constitute a three-dimensional memory array. However, generally speaking, a three-dimensional NAND array may be constructed by tilting a two-dimensional memory structure, such as structures 50 and 210 of FIGS. 4A-B and 5, respectively, in the vertical direction that is perpendicular to the x-y plane (i.e., the z direction), such that each y-z plane of the three-dimensional structure corresponds to the page structure of FIG. 5, wherein each plane is at differing locations along the x axis. As a result, the global bit lines (e.g., BL0, . . . , BLm, of FIG. 5) each run across the top of the memory structure to an associated sense amplifier (e.g., SA0, . . . , SAm). Accordingly, the word lines (e.g., WL0, . . . , WLn, of FIG. 5), and the source and select lines (e.g., SSL0, . . . , SSLn, and DSL0, . . . , DSLn, respectively) extend in the x direction, with the bottom of each NAND string (e.g., string 50) connected to a common source line.

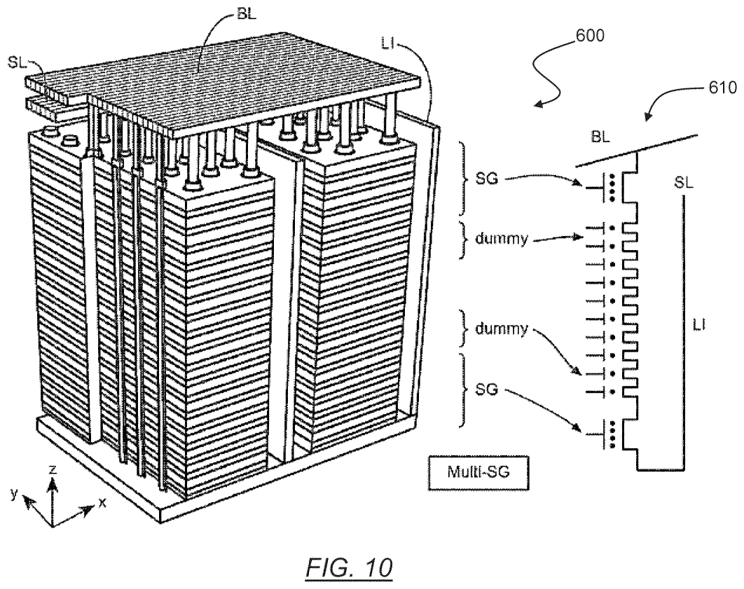

Referring now to FIG. 10, there is depicted an oblique perspective view of an example subsection of an embodiment of a three-dimensional NAND memory array 600 of the Bit Cost Scalable (“BiCS”) type in which one or more memory device levels is formed above a single substrate. The example subsection corresponds to two of the page structures shown in FIG. 4B wherein, depending upon the particular embodiment, each may correspond to a separate memory block or may be different extensions of the same block. According to this embodiment, rather than lying in the same y-z plane, the NAND strings are pressed in the y-direction such that the NAND strings have a staggered configuration in the x-direction. Further, at the top of the array 600, the NAND strings are connected along global bit lines (BL) that span multiple of these subsections of the array 600 that run in the x-direction. In addition, global common source lines (SL) also run across multiple subsections of the memory array 600 in the x-direction and are connected to the sources at the bottom of the NAND strings by a local interconnect (LI) that operates as the local common source line of the individual extension. However, dependent upon the embodiment, the global source lines (SL) can span the whole, or just a subsection, of the memory array 600. Depicted on the right side of FIG. 10 is a schematic representation of the fundamental elements of one of the vertical NAND strings 610 of the memory array 600. Similar to the NAND string 50 of FIG. 4A, the string 610 is comprised of a series of interconnected memory cells. The string 610 is connected to an associated bit line (BL) through a drain select gate (SGD). A source select gate (SDS) connects the string 610 to a global source line (SL) through an associated local source line (LI). Further included in this particular embodiment are several dummy cells located at the ends of the string 610. Due to their proximity to select gates (SGD, SDS) and, thereby, their susceptibility to disturbs, the dummy cells are not used to store user data.

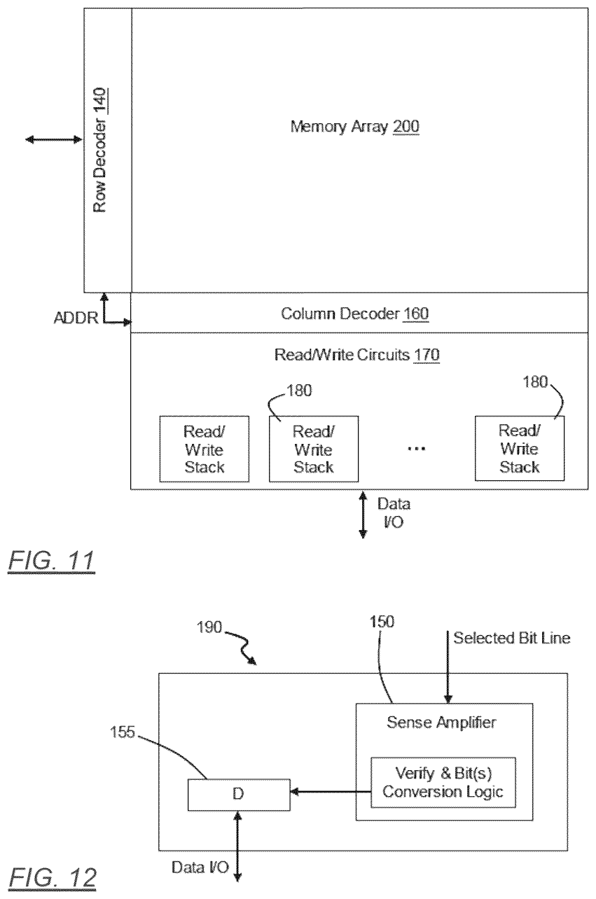

Referring back to the overall architecture of a memory system that is, for example, depicted in FIG. 1, a schematic depiction of a typical arrangement of a memory array of such a system is illustrated in FIG. 11. In this exemplary embodiment, there is shown a non-volatile memory array 200 that is accessible by read/write circuits 170 by way of row decoder 140 and column decoder 160. As previously described above, individual memory cells of the memory array 200 are addressable via a set of selected word line(s) and bit line(s). Accordingly, the row decoder 140 selects one or more word lines and the column decoder 160 selects one or more bit lines in order to apply the appropriate voltages to the respective gates of the addressed memory cells. Further, read/write circuits 170 are provided to read or write the memory states of the addressed memory cells, wherein the read/write circuits 170 comprise a number of read/write modules connectable via bit lines to the memory elements of the array 200. A schematic block diagram of such a read/write module 190 is provided in FIG. 12, according to an exemplary embodiment thereof. In operation, during a read or verify step, a sense amplifier 150 determines the current that is flowing through the drain of an addressed memory cell that is connected via a selected bit line. The level detected by the sense amplifier 150 is converted by a level-to-bits conversion logic to a set of data bits to be stored in a data latch 155. Now referring back to FIG. 11, the read/write circuits 170 are organized into banks of read/write stacks 180 wherein each read/write stack 180 is a stack of read/write modules 190.

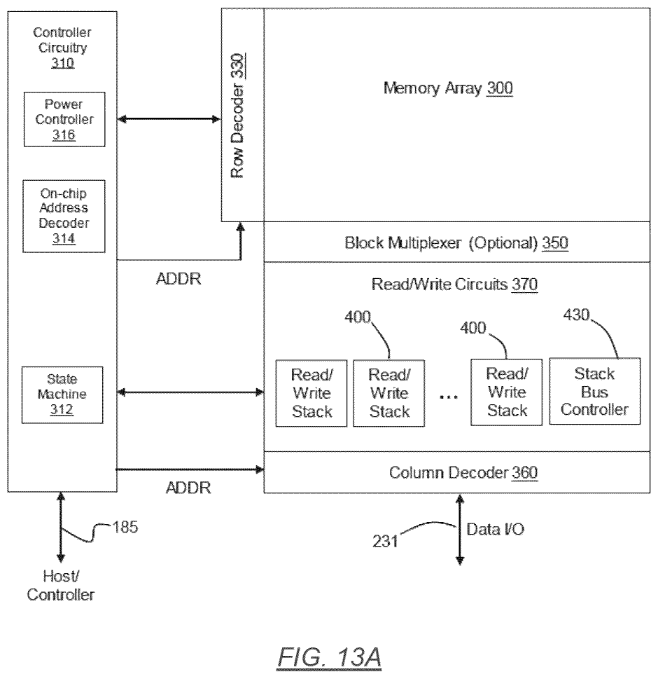

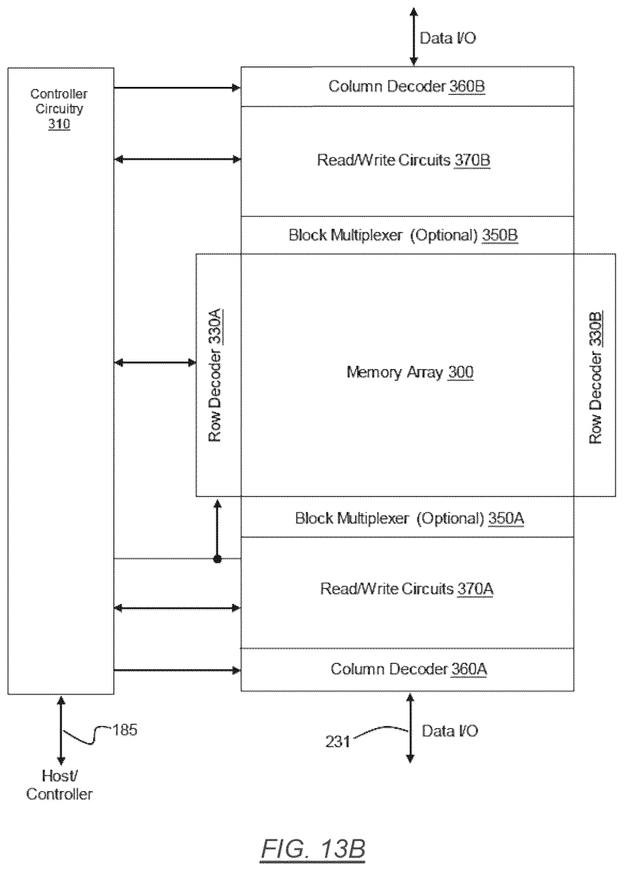

Referring now to FIG. 13A, there is shown an exemplary embodiment of a memory device (such as memory device 102 in FIG. 1, for example) that is comprised of a non-volatile memory array 300 (which may include the NAND-type SLC, MLC, TLC, and/or QLC memory cells that are in a two- or three-dimensional configuration), control circuitry 310, and read/write circuits 370. Further, as is depicted, read/write circuits 370 are comprised of one or more banks of partitioned read/write stacks 400, thereby allowing a block (or “page”) of memory cells to be read or programmed in parallel wherein, according to an exemplary embodiment, a “page” of memory cells constitutes a contiguous row of memory cells. Memory array 300 is addressable by word lines via row decoder 330 and by bit lines via column decoder 360. Alternatively, the memory array 300 may comprise rows of memory cells partitioned into multiple blocks or pages. Hence, in such an exemplary embodiment, a block multiplexer 350 is provided to multiplex the read/write circuits 370 to the individual blocks.

With respect to the control circuitry 310, it operates in conjunction with the read/write circuits 370 to perform memory operations on the memory array 300. In this particular embodiment, the control circuitry 310 includes a state machine 312, an on-chip address decoder 314, and a power controller 316. The state machine 312 provides chip level control of memory operations. The on-chip decoder 314 provides an address interface between that that is used by the host or a memory controller to the hardware address used by the decoders 330, 360. Lastly, the power controller 316 controls the power and voltages that are supplied to the word lines and bit lines during memory operations.

FIG. 13B depicts a slightly different exemplary embodiment of the memory device of FIG. 13A. In this particular embodiment, access to memory array 300 by the various peripheral circuits is implemented in a symmetrical manner on opposite sides of the memory array 300. As a result, the access lines and circuitry on each side of the memory array 300 are reduced in half when compared to the configuration in FIG. 13A. Specifically, the row decoder 330 is split into multiple row decoders 330A, 330B, and the column decoder 360 is split into multiple column decoders 360A, 360B. Furthermore, in such an embodiment in which a row of memory cells is partitioned into multiple blocks, block multiplexer 350 is split into multiple block multiplexers 350A, 350B. The read/write circuits 370 are likewise divided into read/write circuits 370A (connecting to bit lines from the bottom of memory array 300) and read/write circuits 370B (connecting to bit lines from the top of memory array 300). Accordingly, the density of the read/write modules (as well as the partitioned read/write stacks 400) is, in essence, reduced by half.

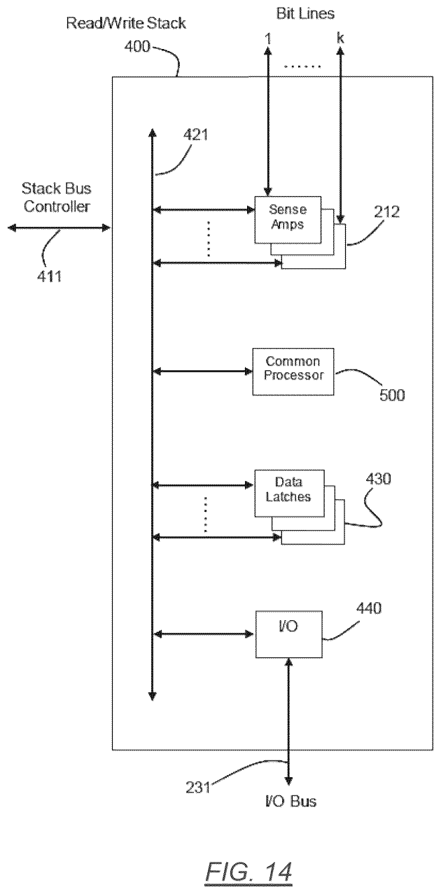

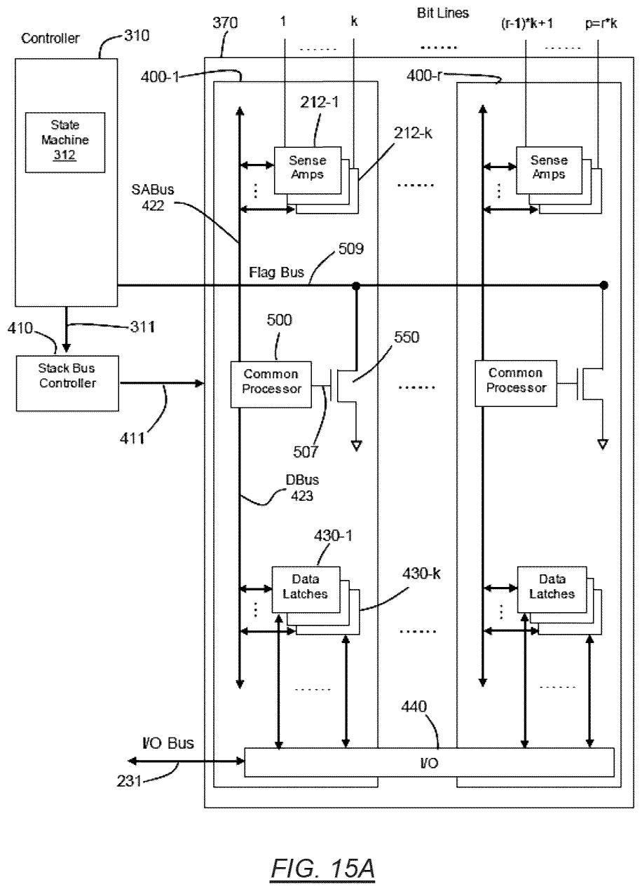

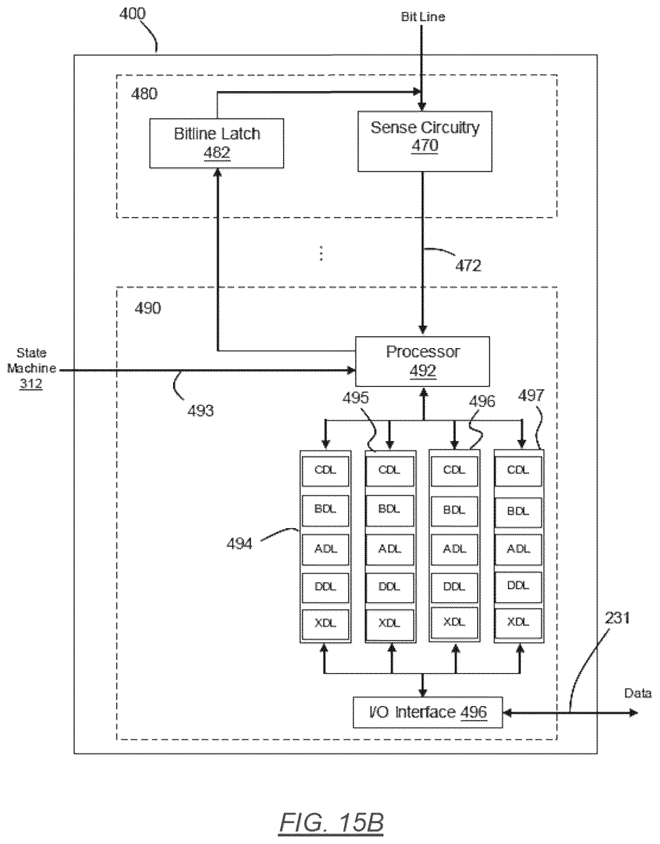

Referring now to FIG. 14, there is illustrated an exemplary embodiment of certain components in a read/write stack, such as the read/write stacks 400 of FIG. 13A. According to this particular architecture, a read/write stack 400 comprises a stack of sense amplifiers 212 for sensing a “k” number of bit lines, an I/O module 440 for input or output of data over an I/O bus 231, a stack of data latches 430 for storing input and/or output data, a common processor 500 to process and store data among the read/write stack 400, and a stack bus 421 for communication among the read/write stack 400 components. In addition, a stack bus controller provides control and timing signals via lines 411 for controlling the various components of read/write stack 400. FIG. 15A depicts an exemplary embodiment for incorporating the read/write stack 400 of the embodiment of FIG. 14 amongst the read/write circuits 370 of the memory devices depicted in FIGS. 13A-13B. As indicated above, each of read/write stacks 400 operates on a group of “k” number bit lines in parallel. Therefore, if a page in memory array 300 has p=r*k bit lines, there will be a “r” number of read/write stacks—i.e., read/write stacks 400-1, . . . , 400-r. Accordingly, the entire bank of partitioned read/write stacks 400-1, . . . , 400-r, operating in parallel allows a block (or a page) of p cells along a row to be read or programmed in parallel, there being p read/write modules for the entire row of cells. As each read/write stack 400-1, . . . , 400-r serves “k” memory cells, the total number of read/write stacks in a bank may be expressed as r=p/k. Further, in accordance with this example, each read/write stack correspondingly has a stack of sense amplifiers 212-1, . . . , 212-k that serves a segment of “k” memory cells in parallel. In addition, each read/write stack correspondingly has a stack of data latches 430-1, . . . , 430-k, wherein each data latch is associated with a memory cell. As such, there is an I/O module 440 enabling data latches 430-1, . . . , 430-k to exchange data externally via an I/O bus 231.

Still referring to FIG. 15A, there is also shown a stack bus controller 410 that receives signals from the memory controller 310 (via lines 311) and in turn provides control and timing signals to the read/write circuits 370 via lines 411. Communication among the read/write stacks 400 is implemented by an interconnecting stack bus controlled by stack bus controller 410. Therefore, the control lines 411 provide control and clock signals from the stack bus controller 410 to the components of the read/write stacks 400-1, . . . , 400-r. In this particular example, the interconnecting stack bus is divided into a SABus 422 and a DBus 423, wherein SABus 422 provides for communication between the common processor 500 and the stack sense amplifiers 212-1, . . . , 212-k, and the DBus 423 provides a communication pathway between the common processor 500 and the stack of data latches 430-1, . . . , 430-k. With respect to the common processor 500, it further comprises an output 507 for output of a status signal of a memory operation, such as an error condition. As is depicted in FIG. 15A, this status signal may, for example, be used to drive a gate of a n-transistor 550 that is tied to a Flag Bus 509 in a Wired-Or configuration, wherein the Flag Bus 509 is pre-charged by the controller 310 and is pulled down when a status signal is asserted by any of read/write stacks 400-1, . . . , 400-r.

Further, an exemplary embodiment of an individual sense block (as encompassed by a read/write stack 400) is depicted in FIG. 15B. Sense block 400 is partitioned into one or more core portions comprising the sense modules 480 or sense amplifiers, and a common portion, referred to as a managing circuit 490. In one embodiment, there is a separate sense module 480 for each bit line and one common managing circuit 490 for a set of multiple, e.g., four or eight, sense modules 480. Each of the sense modules in a group communicates with the associated managing circuit via data bus 472. Thus, there are one or more managing circuits which communicate with the sense modules of a set of storage elements 10.

Sense module 480 comprises sense circuitry 470 that performs sensing by determining whether a conduction current in a connected bit line is above or below a predetermined threshold level. Sense module 480 also includes a bit line latch 482 that is used to set a voltage condition on the connected bit line. For example, a predetermined state latched in bit line latch 482 will result in the connected bit line being pulled to a state designating program inhibit (e.g., 1.5-3 V). As an example, a flag=0 can inhibit programming, while flag=1 does not inhibit programming.

In the exemplary embodiment of FIG. 15B, the managing circuit 490 comprises a processor 492, four example sets of data latches 494, 495, 496, and 497, and an I/O interface 496 coupled between the sets of data latches 494-497 and the data bus 231. One set of data latches may be provided for each sense module 480, and data latches identified by XDL, DDL, ADL, BDL, and CDL may be provided for each set. In some cases, additional data latches may be used. In one exemplary approach, in a memory device which uses eight data states, XDL stores user data, DDL stores an indication of whether quick pass write programming is used, ADL stores a lower page of data, BDL stores a middle page of data, and CDL stores an upper page of data.

Processor 492 performs computations, such as to determine the data stored in the sensed storage element and store the determined data in the set of data latches. Each set of data latches 494-497 is used to store data bits that are determined by processor 492 during a read operation, and to store data bits imported from the data bus 231 during a programming operation which represent write data that is meant to be programmed into the memory. The I/O interface 496 provides an interface between data latches 494-497 and the data bus 231.

During reading, the operation of the system is under the control of state machine 312 that controls the supply of different control gate voltages to the addressed storage element 10. As it steps through the various predefined control gate voltages corresponding to the various memory states supported by the memory, the sense module 480 may trip at one of these voltages and a corresponding output will be provided from sense module 480 to processor 492 via bus 472. At that point, processor 492 determines the resultant memory state by consideration of the tripping event(s) of the sense module and the information about the applied control gate voltage from the state machine via input lines 493. It then computes a binary encoding for the memory state and stores the resultant data bits into data latches 494-497. In another embodiment of the managing circuit 490, the bit line latch 482 operates in a double duty capacity, both as a latch for latching the output of the sense module 480 and also as a bit line latch as described above.

During program or verify operations, the data to be programmed (write data) is stored in the set of data latches 494-497 from the data bus 231. The programming operation, under the control of the state machine 312, comprises a series of programming voltage pulses applied to the control gates of the addressed storage elements. Each program pulse is followed by a read back (verify) to determine if the storage element has been programmed to the desired memory state. In some cases, processor 492 monitors the read back memory state relative to the desired memory state. When the two are in agreement, the processor 492 proceeds to set the bit line latch 482 to cause the bit line to be pulled to a state designating program inhibit. This inhibits the storage element coupled to the bit line from further programming even if program pulses appear on its control gate. In other embodiments, the processor initially loads the bit line latch 482 and the sense circuitry sets it to an inhibit value during the verify process.

As mentioned, each set of data latches 494-497 may be implemented as a stack of data latches for each sense module. In one exemplary embodiment, there are three data latches per sense module 480. In some implementations, data latches are implemented according to a shift register so that the parallel data that is stored therein is converted to serial data for data bus 231, and vice versa. For example, all data latches corresponding to the read/write block of M storage elements can be linked together to form a block shift register so that a block of data can be input or output by serial transfer. In particular, the bank of read/write modules may be adapted in order that each of its set of data latches will shift data into or out of the data bus in sequence as if they are part of a shift register for the entire read/write block.

The data latches identify when an associated storage element 10 has reached certain mileposts in a programming operation. For example, latches may identify if a storage element's Vₜₕ is below a particular verify level. Data latches indicate whether a storage element currently stores one or more bits from a page of data. For example, with respect to one exemplary embodiment, the ADL latch is flipped (e.g., from 0 to 1) when a lower page bit is stored in an associated storage element. Further, the BDL latch is flipped when a middle page bit is stored in an associated storage element. And the CDL latch is flipped when an upper page bit is stored in an associated storage element. A bit is stored in a storage element when the Vₜₕ exceeds an associated verify level.

As mentioned above, these high storage density memory structures, such as the BiCS type described, for example, with respect to the exemplary embodiment shown in FIG. 10, have relatively small spacing between adjacent memory cells and each cell has a relatively small tolerance between discrete voltage ranges for memory functions. Further, with respect to the memory structures that comprise multi-level memory elements or cells, the amount of time necessary to program each state and by, extension, the programming speed obtained, is significantly higher in comparison to the programming time and speed experienced in the programming of single-state memory elements or cells. Accordingly, improving the amount of efficient storage capability within a fixed die size has competing drawbacks and liabilities. Therefore, various approaches may be employed to improve the efficiency of the memory operations. Such measures aim, for example, at permitting the concurrent or simultaneous programming of multiple states, as well as modulating, or otherwise modifying, the amount of programming time that is consumed to program each state.

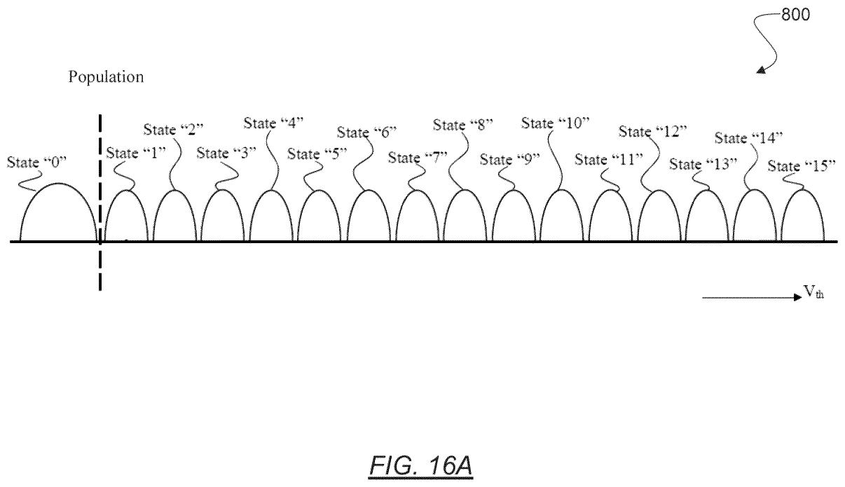

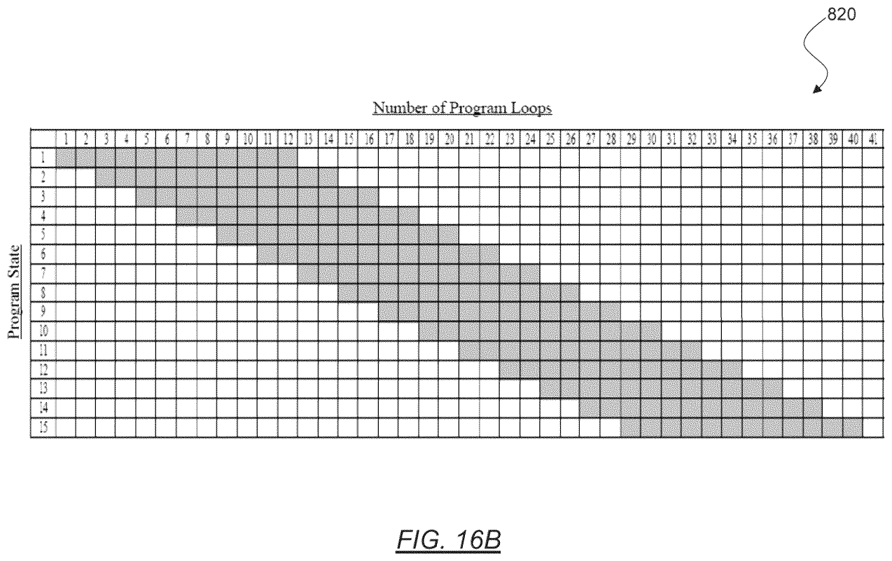

By way of background, FIGS. 16A and 16B intend to illustrate a convention programming approach or methodology according to an exemplary embodiment, wherein the programming operation is applied to, in this particular case, a population of QLC-type NAND memory cells. Accordingly, the programming operation obtains 16 programed states, which are referenced herein as ‘State “0”’ through ‘State “15”’, with ‘State “0”’ constituting the “erased” state. As is generally depicted in the plot distribution diagram 800 provided in FIG. 16A, each program state, i.e., states ‘State “0”’ through ‘State “15”’, comprises a certain population of memory cells that have been programmed according to each program state's respective threshold voltage (Vₜₕ) distribution. Therefore, in a similar manner to the example shown in FIGS. 8A through 8C, the plot distribution depicted in FIG. 16A indicates, for each of the 16 programmed states, the respective threshold voltage (Vₜₕ) distribution that is occupied according to that particular program state. In such a programming operation, in order to program each program state, a programming voltage bias (V_{PGM}) is applied to each word line of the selected memory elements or cells and is incrementally ratcheted up with each successive program state to obtain the steadily increasing threshold voltage (Vₜₕ) distribution that is, in general, illustrated in FIG. 16A.

Referring now to FIG. 16B, there is shown a graphical illustration or graphical representation of the total number of program loops that are required or exhausted in order to program each of program states ‘State “1”’ through ‘State “15”’ in a programming approach according to the embodiment depicted in FIG. 16A. Specifically, at the vertical side of the table 820, each of the program states “1” through “15” are indicated. Further, the total number of program loops required to program each of program states are correspondingly indicated at the horizontal side of the table 820. Thus, according to this particular programming approach or methodology, the program states are programmed consecutively in serial order such that only a single state is programmed at a time. Therefore, in this particular embodiment, for the sake of illustrative purposes only, such a programming operation may comprise, for example, a total of approximately 40 programming loops, wherein the shaded program loops indicate the verify memory operations conducted for each of the program states as is determined by the “natural” threshold voltage (NVₜₕ) distribution or width of each program state. Thus, as a result of this relatively high number of total programming loops needed, a substantial amount of time is consumed in order to complete the programming operation. Axiomatically, a relatively lower programming speed is also experienced, thus reducing the overall efficiency of the memory structure.

Accordingly, to increase the efficiency, and thereby the performance, of high-density multi-state memory structures, it would be beneficial to reduce the amount of time needed to complete a programming operation. Thus, various techniques and methodologies may be employed to effectively decrease the programming time (T_{prog}) that is expended during a programming cycle. For example, with respect to the programming operation itself, it may be possible, according to certain exemplary embodiments, to concurrently or to simultaneously program two or more program states at a time rather than proceeding to program only a single program state at a time in a serial or sequential manner (e.g., according to the programming approach or methodology that is described above in connection with FIGS. 16A and 16B). Therefore, the amount of time required to complete a programming operation using such a programming approach is significantly lessened by the sheer ability to program more than one program state at a time and/or during the same time period.

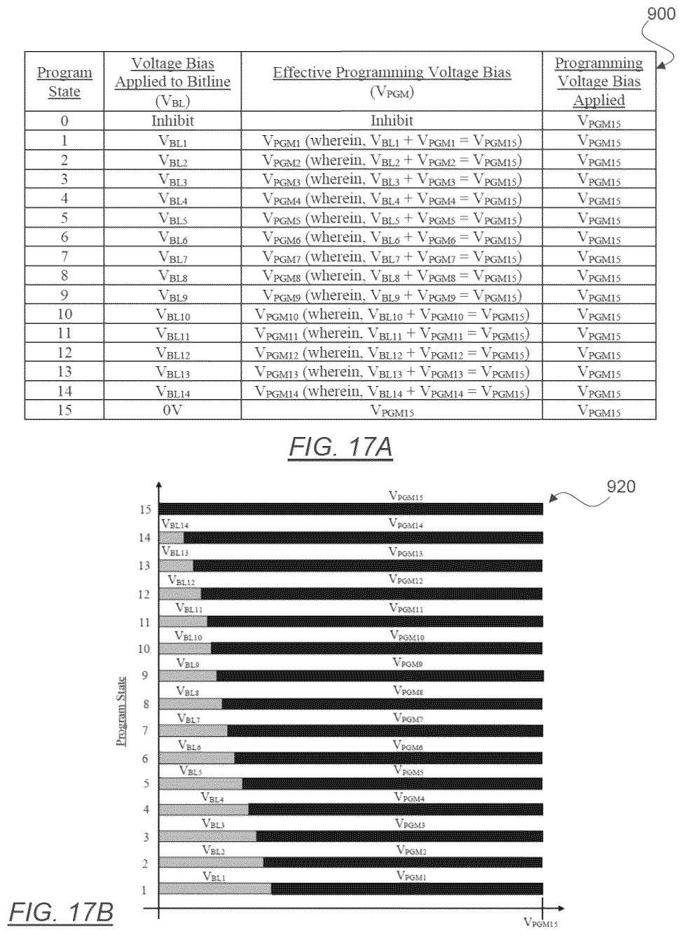

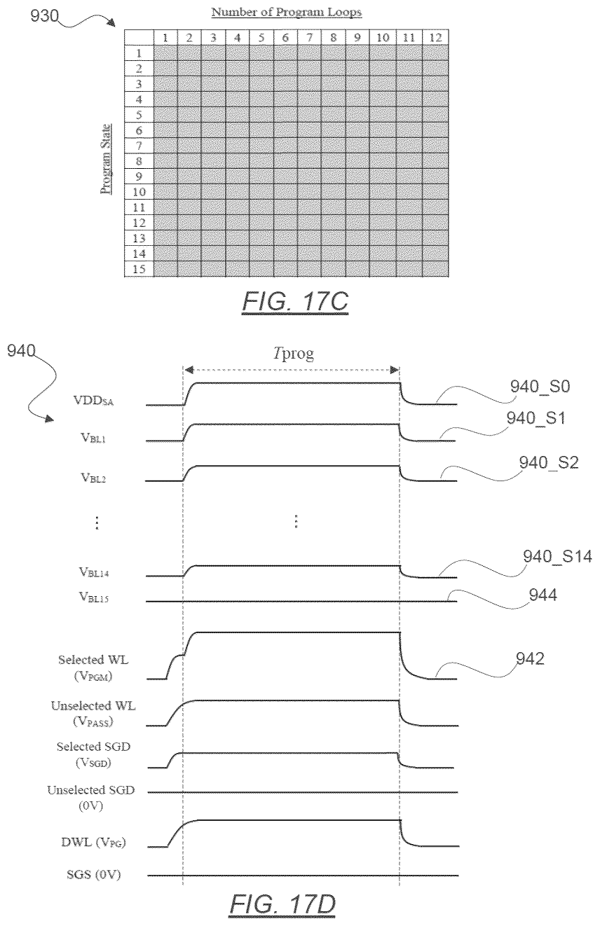

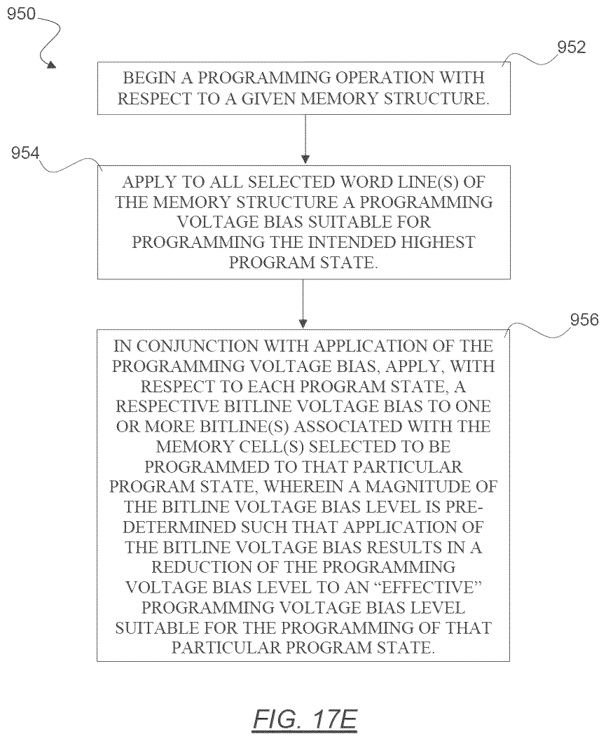

For instance, depicted in FIGS. 17A through 17D is one non-limiting example of a “multi-state” programming operation according to an exemplary embodiment. For illustrative purposes only, this particular embodiment is described as applied to a memory structure that comprises QLC NAND-type memory elements or cells. As such, the programming operation is conducted with respect to 16 program states (i.e., program states “0” through “15,” wherein program state “0” is an “erased” state). However, the programming operation that is detailed below may be applied to any memory structure that comprises “multi-level” (e.g., MLC, TLC, etc.) memory elements or cells. Beginning with FIG. 17A, provided is a “lookup” table or chart 900 that indicates, for each of the program states “0” through “15,” a respective programming voltage bias (V_{PGM}) is applied to the one or more word lines (WLs) of the selected memory element(s) or cell(s) during the programming operation of a subject memory structure. Importantly, unlike the serial order programming operation approach as described above with respect to, for example, FIGS. 16A and 16B, in which the applied programming voltage bias (V_{PGM}) is incrementally changed or adjusted for each program state, the same programming voltage bias (V_{PGM}) is applied to each of the one or more word lines of the selected memory element(s) or cell(s). More specifically, as set forth in the table 900 of FIG. 17A, a lone programming voltage bias (i.e., V_{PGM15}) is commonly applied to each word line during the programming operation, wherein the magnitude of this specific programming voltage bias (V_{PGM15}) is large enough to successfully program the highest program state that is to be programmed. Accordingly, in this particular example, the highest program state that is to be programmed is program state “15” and, as such, the magnitude of the singular applied programming voltage bias (V_{PGM15}) may be any voltage level that, as determined according to experimental and/or in situ data and observations, is suitable for effectively programming the program state “15.” Given the fact, however, that the single application of this relatively substantial programming voltage bias (V_{PGM15}) will result in the programming of all selected memory element(s) or cell(s) to the highest program state (in this example, program state 15″), a countering bitline voltage bias (V_{BL}) must also be applied to the selected individual bitline(s) in conjunction with the programming voltage bias (V_{PGM15}) in order to ensure the programming of the lower program states (in this example, program states “1” through “14”) as well. More specifically, according to, for example, the embodiment that is set forth in the table 900 of FIG. 17A, in order to program each of program states “1” through “14”, a corresponding bitline voltage bias, i.e., V_{BL1} for program state “1”, V_{BL2} for program state “2”, . . . , V_{BL14} for program state “14”, is applied to the one or more bitline(s) associated with the selected one or more memory element(s) or cell(s), thereby producing an “effective” programming voltage bias (V_{PGM}) that is lower than the elevated “applied” programming voltage bias (i.e., V_{PGM15}) and suitably in line with the programming voltage bias needed to effectively program each of the program states “1” through “14.” Accordingly, as set forth in the table 900, with respect to program state “1”, a bitline voltage bias (V_{BL1}) is applied, which essentially reduces the programming voltage bias (V_{PGM15}) being applied to an “effective” programming voltage bias (V_{PGM1}), wherein V_{PGM1}=V_{PGM15}−V_{BL1}. As a result, under these conditions, the memory element(s) or cell(s) selected for programming to program state “1”, experience an “effective” programming voltage bias (V_{PGM1}) that is suitable for, and does not exceed, the programming voltage bias that would otherwise correspond to program state “1.” Furthermore, while now ensuring that the program state “1” is effectively programmed, the memory element(s) or cell(s) selected for programming to program state “15” are also beneficially being programmed to program state “15” in parallel, or concurrently, with the programming of program state “1” by virtue of the high programming voltage bias (V_{PGM15}) that is universally being applied to the selected word line(s).

Further, as generally depicted in table 900, the remaining program states “2” through “14” may also be similarly programmed by applying, for each program state, a specific pre-determined bitline voltage bias (V_{BL}) to the appropriate bitline(s) that will suitably adjust the applied programming voltage bias to an “effective” programming voltage bias (V_{PGM}) that is commensurate with the intended or desired program state. For example, as shown in table 900, with respect to program state “2”, a pre-determined bitline voltage bias (V_{BL2}), that is different from the bitline voltage bias (V_{BL1}) applied to program the program state “1,” is applied to the appropriate bitline(s). As a result, the programming voltage bias experienced by the selected memory element(s) or cell(s) being programmed to the program state “2” is decreased from the applied programming voltage bias (V_{PGM15}) to an “effective” programming voltage bias (V_{PGM2}) that is now well-suited for programming the program state “2.” Likewise, with respect to the program state “3,” a respective pre-determined bitline voltage bias (V_{BL3}), different from both bitline voltage biases applied in connection with the program states “1” and “2” (i.e., V_{BL1} and V_{BL2}, respectively), is applied to the appropriate bitline(s) in order to decrease the applied programming voltage bias (V_{PGM15}) to an “effective” programming voltage bias (V_{PGM3}) that is proper for programming the program state “3.” Accordingly, as illustrated in table 900, the program states “1” through “15” may be simultaneously programmed in this same manner by precisely adjusting or fine-tuning the relatively high programming voltage bias (V_{PGM15}) (that is universally applied) to the appropriate “effective” programming voltage bias for each program state by, in conjunction, applying a respective bitline voltage bias (V_{BL}) pre-determined for each program state. As a result of this programming approach, the efficiency of the programming operation is vastly improved by this ability to program more than one program state during the same time period.

Referring now to FIG. 17B, there is shown a graphical illustration of the relationship between the bitline voltage bias (V_{BL}), the applied programming voltage bias (V_{PGM15}), and the “effective” programming voltage bias (V_{PGM}) for each program state “1” through “15”, in accordance with the programming operation of the exemplary embodiment described above in connection with table 900 of FIG. 17A. As indicated along the right-hand side of the bar graph 920, a single applied programming voltage bias (V_{PGM15}) level, namely a programming voltage bias level that is sufficient to effectively program the highest program state (i.e., program state “15”), is globally applied to the appropriate word line(s) with respect to each program state “1” through “15.” However, in addition to the applied programming voltage bias (V_{PGM15}), a respective bitline voltage bias (V_{BL1}. V_{BL}2, . . . , V_{BL14}) is also applied to the appropriate bitline(s) with respect to each program state. Accordingly, for illustrative purposes, the one or more respective bitline voltage biases (V_{BL}) that are applied with respect to each program state are indicated by the “grey” portion of each bar of the bar graph 920. Furthermore, for each of the program states, the effect of the bitline voltage bias on the programming voltage bias (V_{PGM}) experienced by the selected memory element(s) or cell(s) is demonstrated in bar graph 920. Specifically, for each program state, the associated bar of the bar graph 920 indicates that the applied programming voltage bias (V_{PGM15}) is reduced by the voltage amount equal to the respective bitline voltage bias (V_{BL}) such that there remains an adjusted, or an “effective”, programming voltage bias (V_{PGM}), as denoted by the “black” portion of the bar. Therefore, as shown in bar graph 920, the applied programming voltage bias (V_{PGM15}) is equal to, for each program state, the sum total of the bitline voltage bias (V_{BL}) and the resulting “effective” programming voltage bias (V_{PGM}). As is also shown in the bar graph 920, the magnitude of the applied bitline voltage bias (V_{BL}) level steadily decreases as the program states increase from program state “1” to program state “15”. Therefore, as a result, the “effective” programming voltage bias (V_{PGM}) level will steadily increase as is necessary with each higher program state. According to certain embodiments, the pre-determined bitline voltage bias (V_{BL}) level may incrementally increase with respect to each higher program state, wherein the increment is identical between each program state. Alternatively, according to other embodiments, the pre-determined may incrementally increase with respect to each higher program state, wherein the increment is variable and/or nonidentical between each program state.

With respect to FIG. 17C, there is shown, in a similar manner to FIG. 16B, a graphical illustration or graphical representation of the total number of program loops that are required in order to program each of program states ‘State “1”’ through ‘State “15”’ in a programming approach according to the embodiment depicted in FIGS. 17A and 17B. Relative to the serial programming approach that is depicted in FIGS. 16A and 16B, in which only a single program state is programmed at time, the number of program loops is comparatively far less when the concurrent programming approach pictured in FIGS. 17A and 17B is employed. Specifically, according to this particular example, approximately just 12 program loops (which include the verify memory operation(s)) are needed to complete the programming operation; whereas, as discussed above, approximately 40 program loops are required in order to complete the programming operation depicted in FIGS. 16A and 16B. Therefore, due to the ability to now program multiple program states at a time, the efficiency of the programming operation is significantly improved.

Turning now to FIG. 17D, there is depicted, in general terms, a signal timing diagram 940 that indicates the various voltage biases that are applied during a single program pulse (comprising a programming time period referenced as T_{prog}) in accordance with the concurrent programming operation or methodology that was described above with respect to FIGS. 17A through 17C. In pertinent part, as indicated in FIG. 17D, the signal 942 is representative of the single programming voltage bias (V_{PGM15}) level that is pre-determined as sufficiently high to effectively program the highest program state, i.e., program state “15.” Accordingly, as was described above, this sizable single programming voltage bias (V_{PGM15}) is, according to the concurrent programming operation of this particular embodiment, universally applied to each of the word line(s) associated with the memory element(s) or cell(s) selected to be programmed. Further, the signal 940_S0 indicates the input voltage bias (VDD_{SA}) that produces an “inhibit” condition that is associated with an “erased” state with respect to selected memory element(s) or cell(s). Next, the signal 940_S1 is representative of the bitline voltage bias (V_{BL1}) that, as described above, is applied to the bitline(s) associated with the memory element(s) or cell(s) selected to be programmed to the program state “1.” As discussed above, the respective bitline voltage biases (V_{BL}) applied during the programming operation are intended to effectively decrease or reduce the overtly high programming voltage bias (V_{PGM15}) applied therein to an “effective” programming voltage bias (V_{PGM}) that is suitable for programming of the lower program state. Similar to signal 940_S1, signal 940_S2 indicates the bitline voltage bias (V_{BL2}) that is applied to the appropriate bitline(s) associated with the memory element(s) or cell(s) that are selected to be programmed to the program state “2.” Accordingly, as described above with respect to, for example, FIG. 17B, the magnitude of the voltage of signal 940_S2 is, when compared to the magnitude of the voltage of signal 940_S1, lower by a pre-determined voltage amount. For the sake of brevity and ease of illustration, individual bitline voltage bias (V_{BL}) signals with respect to program states “3” through “13” are not depicted in the signal timing diagram 940 of FIG. 17D. However, each of the bitline voltage bias signals “V_{BL}3” through “V_{BL}13” would have the same characteristics as the waveforms of voltage signals 940_S1 and 940_S2 with the exception that, as described above, the magnitude of the bitline voltage bias applied gradually decreases with each higher program state. Therefore, as is indicated in FIG. 17D, with respect to the last program state in which a bitline voltage bias (V_{BL14}) is applied according to this particular embodiment (i.e., program state “14”), the voltage signal 940_S14 substantially mimics the waveform of that of signals 940_S1 and 940_S2. However, signal 940_S14 necessarily has the lowest magnitude within the set of bitline voltage bias (i.e., V_{BL1} through V_{BL14}) signals applied during the program pulse that is depicted in the signal timing diagram 940.

Lastly, with respect to the highest program state (i.e., program state “15”) in this particular embodiment, as demonstrated by the zero volts shown at 944 in the signal timing diagram 940 in FIG. 17D, no bitline voltage bias (V_{BL15}) is applied. As a result, the bitline(s) associated with the memory element(s) or cell(s) that are selected to be programmed to program state “15” are subjected to, or experience, the entire charge of the applied programming voltage bias (V_{PGM15}) indicated at signal 942.

With respect to FIG. 17E, there is provided a flow diagram 950 that, in general terms, outlines several steps of the concurrent programming operation according to the exemplary embodiment described above with respect to FIGS. 17A through 17D. Beginning at step 952, a programming operation is initiated with respect to a given memory structure. Thereafter, at step 954, a programming voltage bias (V_{PGM}) is applied to all selected word line(s) of the memory structure, wherein a magnitude of the programming voltage bias (V_{PGM}) is suitable for programming the intended highest program state according to the programming operation. Further, at step 956, in addition to, or in conjunction with, the application of the programming voltage bias (V_{PGM}), a respective bitline voltage bias (V_{BL}) with respect to each program state is applied to the one or more bitline(s) associated with the memory element(s) or cell(s) selected to be programmed to that particular program state. As further noted, a magnitude of the bitline voltage bias (V_{BL}) level is pre-determined such that application of the bitline voltage bias (V_{BL}) results in a reduction of the applied programming voltage bias (V_{PGM}) level to an “effective” programming voltage bias level that is suitable for the programming of that particular program state.

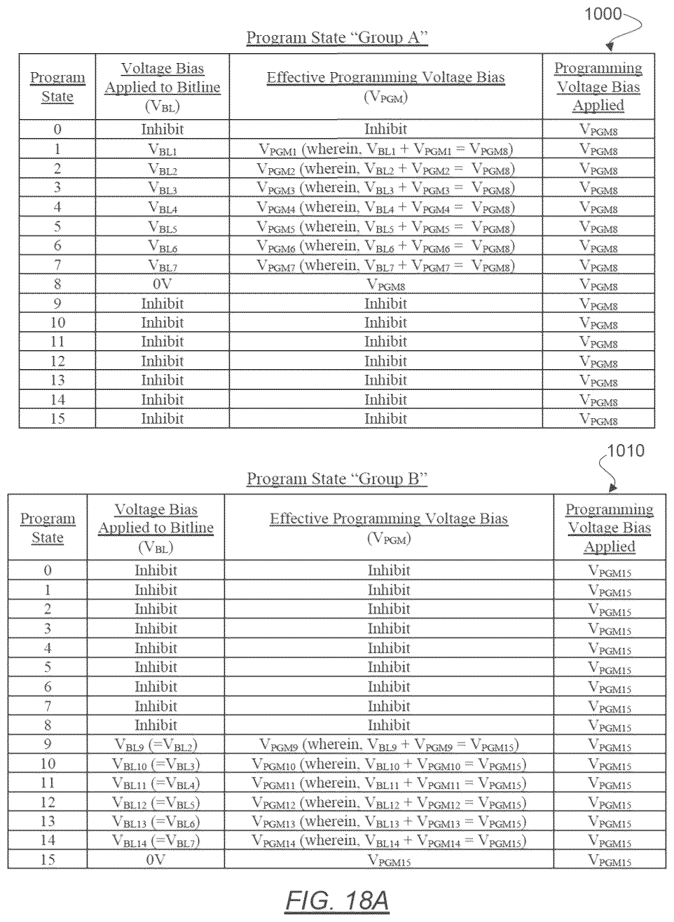

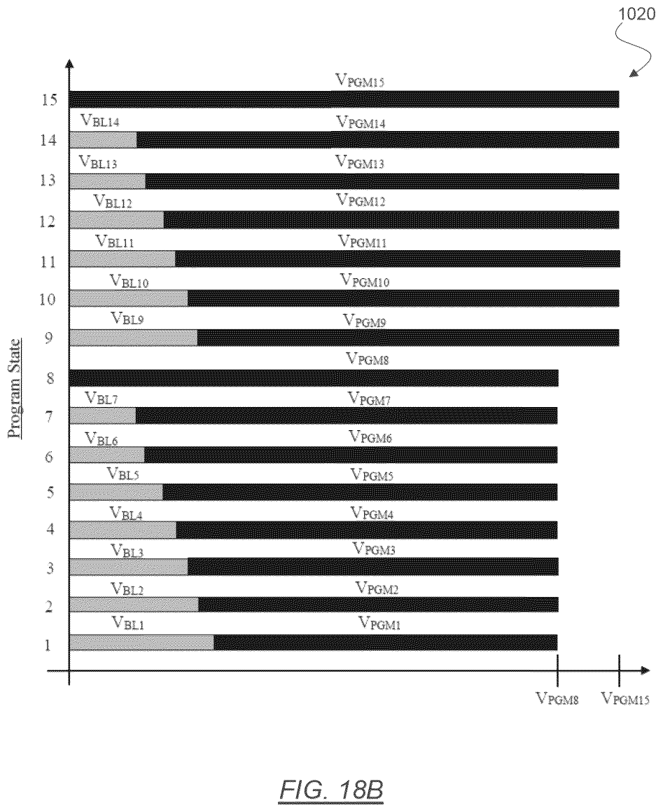

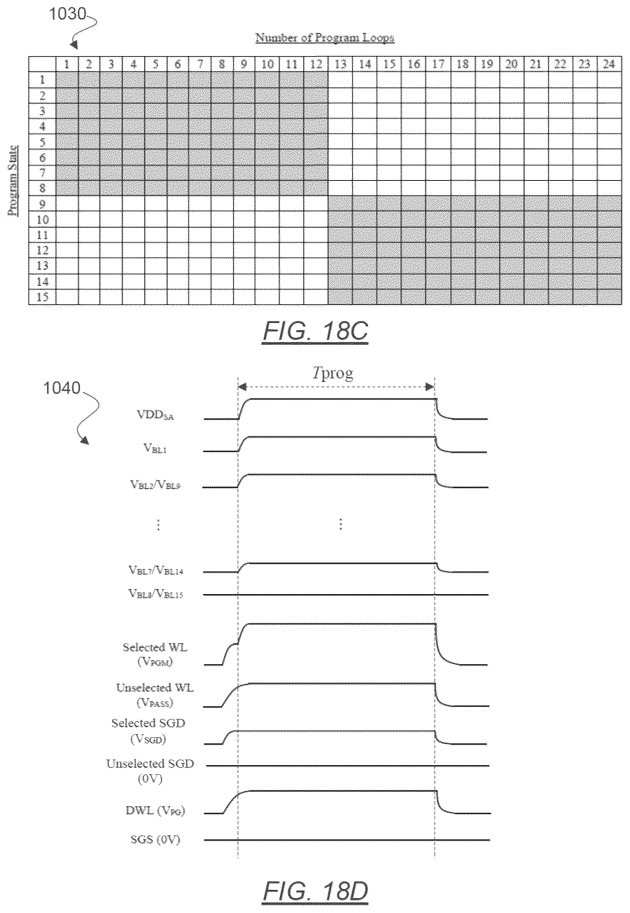

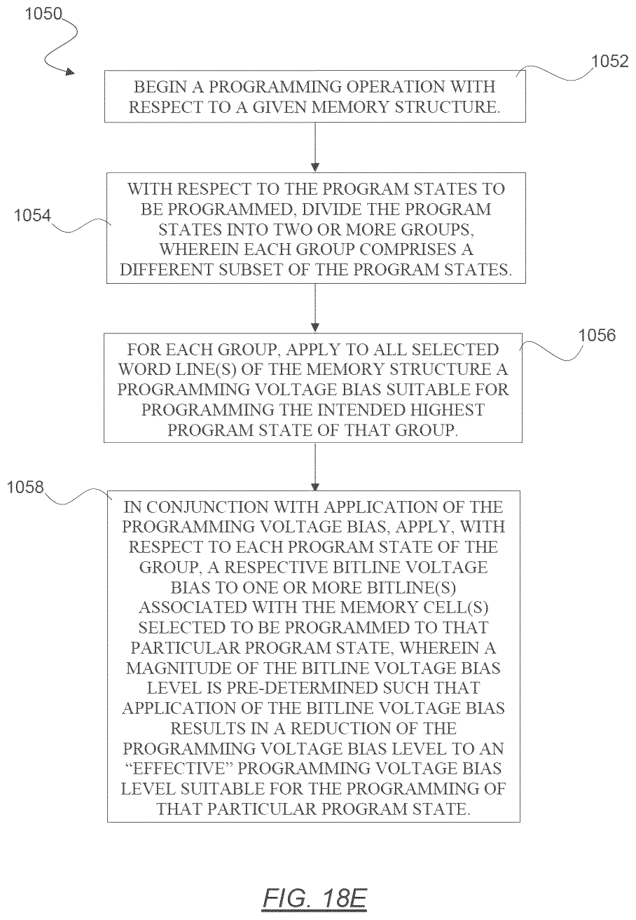

Although the ability to program multiple states during the same time in a concurrent programming approach may, relative to a serial programming approach, dramatically reduce the duration of time (T_{prog}) that is required to complete a programming operation, a concurrent programming approach may inherently encounter certain drawbacks or disadvantages. For example, the universal application of the significantly high programming voltage bias (V_{PGM}) (according to the highest program state) to all selected word line(s), as well as the relatively considerable bitline voltage bias (V_{BL}) levels necessarily applied in connection with the lower program states (in order to produce the relatively low “effective” programming voltage bias necessary to program the lower program states), may negatively impact the performance and reliability of the memory structure. For example, these large voltages may consume a hefty amount of power, place a substantial amount of physical or material strain on the various semiconductor materials, and sharply constrain the window for application of the necessary voltage bias (VSGD) to the relevant drain select gates (SGD). Thus, it would be beneficial to modify the concurrent programming approach described above (e.g., such as the exemplary embodiment depicted in FIGS. 17A through 17E) with the aim of reducing some or all of the voltage bias levels being applied during a concurrent programming approach. One exemplary embodiment of such a modified concurrent programming approach will now be described with reference to FIGS. 18A through 18E. It should be noted that, to provide an equal and like comparison between the exemplary embodiments of FIGS. 17A-17E and FIGS. 18A-18E, the embodiment described below with respect to FIGS. 18A-18E is demonstrated as applied to a memory structure that comprises QLC NAND-type memory element(s) or cell(s). Importantly however, the general programming approach or programming framework that is utilized in each of the embodiments of FIGS. 17A-17E and FIGS. 18A-18E may be applied to a non-volatile memory structure comprising memory element(s) or cell(s) of any “multi-level” degree or type (e.g., MLC or TLC).

Beginning at FIG. 18A, depicted therein are two “lookup” tables or charts, 1000 and 1010, respectively. In a similar manner to the “lookup” table or chart 900 described above with respect to FIG. 17A, each of the “lookup” tables 1000 and 1010 indicate, for each of program states “1” through “15,” a respective: (1) applied programming voltage bias, (2) bitline voltage bias (V_{BL}), and (3) “effective” programming voltage bias (V_{PGM}). As described below, the concurrent programming operation according to this particular exemplary embodiment is substantially similar to the concurrent programming operation according to the embodiment described above with respect to FIGS. 17A through 17E. Namely, for each program state, a respective bitline voltage bias (V_{BL}) level is applied to the appropriate bitline(s) in order to sufficiently damper down the outsized voltage level of the programming voltage bias (V_{PGM}) universally applied to the selected word line(s). In this way, multiple program states may be programmed at the same time by producing, for each lower program state (i.e., other than the highest program state), an “effective” programming voltage bias that is appropriate for, or commensurate with, the programming requirements of each lower program state. However, as mentioned above, to combat the potential strain from the high programming voltage bias and bitline voltage bias levels, the programming approach according to this alternative exemplary embodiment somewhat diverges or deviates from the previously described programming approach. Specifically, rather than programming all 16 program states (i.e., States “1” through “15”) simultaneously, the programming operation may be divided into two or more separate groups.

For example, according to the exemplary embodiment set forth in FIG. 18A, the programming operation may be divided into two distinct groups, which are referenced herein as “Group A” and “Group B.” Accordingly, as indicated in table 1000, “Group A” only comprises programming States “1” through “8.” Further, as indicated in table 1010, “Group B” only comprises programming States “9” through “15.” Beginning with program state “Group A” and the information provided in table 1000, it is clear that, rather than applying the programming voltage bias (V_{PGM15}) that is sufficient for programming the highest program state of the 16 program states, only the programming voltage bias (V_{PGM8}) sufficient to program the highest program state within “Group A” (i.e., program State “8”) is now applied to the selected word line(s) of the memory structure for the purpose of programming just program State “1” through State “8.” Still yet, the applied programming voltage bias (V_{PGM8}) exceeds the programming voltage biases needed to program States “1” through “7” concurrently with State “8.” Thus, as indicated in table 1000, a respective bitline voltage bias (V_{BL}) is applied to the appropriate bitline(s) with respect to each lower program state (i.e., States “1” through “7”) in order to effectively lower the excessive applied programming voltage bias (V_{PGM8}) to an appropriate voltage level for each program state. Accordingly, with respect to the program State “1,” table 1000 provides that a respective bitline voltage bias (V_{BL1}) is applied to the appropriate bitline(s) associated with the memory element(s) or cell(s) that are selected to be programmed to program State “1.” As indicated in table 1000, application of the bitline voltage bias (V_{BL1}) effectively decreases the applied programming voltage bias (V_{PGM8}) to an “effective” programming voltage bias (V_{PGM1}) that is suitable for the programming of program State “1,” wherein V_{PGM8}−V_{BL1}=V_{PGM1}. Likewise, the remaining program states of “Group A” (i.e., States “2” through “7”) are programmed by applying, for each program state, a respective bitline voltage bias (i.e., voltage biases V_{BL2}, V_{BL}3, . . . , V_{BL7}) level that is pre-determined in order to methodically decrease the applied programming voltage bias (V_{PGM8}) to an “effective” programming voltage bias (i.e., voltage biases V_{PGM2}, V_{PGM}3, . . . , V_{PGM7}) level that, when employed, is in conformity with the programming requirements of the program state at hand. As a result of this programming approach, the program States “1” through “8” may be programmed concurrently. As further depicted in table 1000, an inhibit condition is applied to prevent the programming of State “9” through State “15” (i.e., the program states designated as “Group B”).

Moving onward, with respect to the programming of program state “Group B,” table 1010 indicates that, in order to program just program State “9” through State “15,” an inhibit condition is imposed with respect to program State “1” through State “8.” Further, a single programming voltage bias (V_{PGM15}) is applied to all selected word line(s), wherein the voltage level is pre-determined as suitable for effectively programming the highest program state of “Group B,” i.e., program State “15.” Additionally, in an analogous manner to the programming of the lower program States “1” through “7” of “Group A,” a pre-determined respective bitline voltage bias (V_{BL}) is applied, for each of the program States “9” through “14,” in order to effectively reduce the overtly high applied programming voltage bias (V_{PGM15}) level to an “effective” programming voltage bias (V_{PGM}) level that is suitable for the programming of the applicable program state. Accordingly, with respect to program State “9,” as indicated in table 1010, a respective bitline voltage bias (V_{BL9}) is applied to the specific bitline(s) associated with the memory element(s) or cell(s) selected to be programmed to the program State “9.” Thus, as shown in table 1010, as a result of the applied bitline voltage bias (V_{PGM9}), the programming voltage bias (V_{PGM15}) level is systematically decreased by the magnitude of the applied bitline voltage bias (V_{BL9}) to arrive at an “effective” programming voltage bias (V_{PGM9}) level that is attuned to the programming requirements of the program State “9.” Therefore, as indicated in table 1010, V_{PGM15}−V_{BL}9=V_{PGM9}.

Further, as depicted in table 1010, with respect to the programming of the remaining lower program states of “Group B,” i.e., program States “10” through “14,” an identical programming approach is utilized. Namely, for each of the program states, a respective bitline voltage bias (i.e., V_{BL10}, V_{BL11}, . . . , V_{BL14}) level is specifically selected and applied in order to adjust or fine-tune the universally applied programming voltage bias (V_{PGM15}) level to a proper and consonant level for the program state that is being programmed. As a result, the program States “9” through “15” may be concurrently programmed. As also depicted in table 1010, an inhibit condition is applied to prevent the programming of State “0” through State “8” (i.e., the program states designated as “Group A”).

Importantly, it should be noted that, by dividing or fragmenting the concurrent programming operation into separate groups (or subsets) within the complete array of program states, not every one of the program states will be subject to the exceedingly high programming voltage bias (V_{PGM}) level that corresponds to the very highest program state possible within the complete array. For example, as mentioned above in the case of the exemplary embodiment depicted in FIG. 18A, in which the programming operation is bifurcated into two groups, i.e., “Group A” and “Group B,” the program states within “Group A” were only subject to the somewhat high programming voltage bias (V_{PGM8}) corresponding to the program State “8” (wherein program State “8” is the highest program state within “Group A”). This voltage bias is significantly less than the larger magnitude programming voltage bias (V_{PGM15}) that would otherwise be applied if the programming operation was not bifurcated. Furthermore, due to the fact that the program states in “Group A,” which comprise the lower half of the program states within the complete program state array, are subject to this more modest programming voltage bias (V_{PGM8}), the respective bitline voltage biases (V_{BL}) can also have a comparatively lower magnitude in order to arrive at the same “effective” programming voltage bias (V_{PGM}) that is sufficient to program the particular program state. For the sake of illustration, the following numerical case may be considered. For this example, it may be assumed that the “effective” programming voltage bias (V_{PGM1}) level that is required in order to sufficiently program the program State “1” is 14.5 volts. Further, it may be assumed that the programming voltage bias (V_{PGM15}) level needed to sufficiently program the very highest program state, i.e., the program State “15,” is 20 volts. Accordingly, in the event that the type of concurrent programming operation does not involve delineating the programming operation into two or more groups or subsets (such as in the exemplary embodiment depicted in FIGS. 17A through 17E), a 5.5-volt bitline voltage bias (V_{BL1}) must be applied in order to effectively bring down the 20-volt programming voltage bias (V_{PGM15}) to the requisite 14.5 volts (V_{PGM1}) (wherein 20 volts−14.5 volts=5.5 volts). By contrast, should the programming operation be divided into, for example, two program state groups (such as in the exemplary embodiment depicted in FIG. 18A), and wherein program State “1” is positioned within a first group that comprises program States “1” through “8,” the highest program state within this first group is now program State “8.” Accordingly, the programming voltage bias (V_{PGM8}) level that is universally applied during the programming of program State “1” will now necessarily be significantly lower in magnitude relative to the requisite 20-volt programming voltage bias (V_{PGM15}) level that corresponds to program State “15.” For example, the program State “8” may require only a 17.5-volt programming voltage bias (V_{PGM8}) level. As a result, the bitline voltage bias (V_{BL1}) needed to reduce the 17.5-volt applied programming voltage bias (V_{PGM8}) level to the requisite 14.5-volt “effective” programming voltage bias (V_{PGM1}) level that is needed to program State “1,” is now just 3.0 volts (wherein 17.5 volts−14.5 volts=3 volts). Accordingly, by dividing the programming operation into groups, it may be possible, with respect to at least a subset of the program states, to advantageously decrease both the applied programming voltage bias level (V_{PGM}) and the bitline voltage bias level(s) (V_{BL}) that are employed, thereby safeguarding the physical and material integrity of the memory structure and the reliability of the programming operation.

Further, it should be noted that the programming operation may be divided into more than two groups of program states. The exemplary embodiment that is depicted in FIG. 18 is intended to be only one non-limiting example that illustrates the overall general concept of delineating a concurrent programming operation into multiple program state groups as a mechanism for scaling back (or scaling down) the respective magnitudes of the several voltage bias levels.

In a manner similar to bar graph 920 in FIG. 17B, FIG. 18B provides a graphical illustration (in the form of a bar graph 1020) of, for each program state, the relationship or dependency between the universally applied programming voltage bias, the bitline voltage bias (V_{BL}), and the resulting “effective” programming voltage bias (V_{PGM}), in accordance with the programming operation of the exemplary embodiment of FIG. 18A. Further, bar graph 1020 provides a useful side-by-side visual comparison between the voltage bias levels applied with respect to the program states that comprise “Group A” (i.e., States “1” through “8”) and with respect to the program states that comprise “Group B” (i.e., States “9” through “15”). Each program state is indicated along the vertical axis of the bar graph 1020. In addition, indicated along the horizontal axis of the bar graph 1020 is the voltage bias level applied during the programming operation with respect to each program state. For illustrative purposes, the respective bitline voltage bias (V_{BL}) level that is applied with respect to each program state is indicated by the “grey” portion of each bar of bar graph 1020. Furthermore, for each program state, the moderating effect of the bitline voltage bias (V_{BL}) on the programming voltage bias (which is either a voltage level “V_{PGM}8” in the case of “Group A,” or is a higher voltage level “V_{PGM}15” in the case of “Group B”) that is experienced by the selected memory element(s) or cell(s), is demonstrated in bar graph 1020. Specifically, for each program state, the applied programming voltage bias is reduced by a voltage amount that is equal in magnitude to the respective bitline voltage bias (V_{BL}) such that there remains an adjusted, or an “effective,” programming voltage bias (V_{PGM}) as denoted by the “black” portion of each bar. As shown in graph 1020 with respect to the program states within “Group A.” the bitline voltage bias (V_{BL}) levels incrementally decrease as the program states increase, thus resulting in the increasingly higher programming voltage bias (V_{PGM}) levels needed to program the higher program states. Likewise, with respect to the program states within “Group B,” there occurs an incremental decrease in the bitline voltage bias (V_{BL}) levels as the program states increase in order to effectively program the higher program states. As mentioned above, the magnitude of the increment in the bitline voltage bias (V_{BL}) level occurring between the program states may be identical with each increment or, alternatively, it may vary, as pre-determined based upon the experimental and/or in situ data and observations.

With respect to FIG. 18C, there is shown, in a similar manner to FIG. 17C, a graphical illustration or representation of the total number of program loops that are required in order to program each of program states ‘State “1”’ through ‘State “15”’ according to the bifurcated concurrent programming approach of the embodiment depicted in FIGS. 18A and 18B. In this case, although the program states are concurrently programmed, the bifurcation divides the programming operation into a first programming stage and a second programming stage. In the first programming stage, the program states of “Group A” (i.e., States “1” through “8”) are concurrently programmed. According to this example, as shown in the table 1030 of FIG. 18C, this first programming stage comprises approximately 12 program loops (including the verify memory operation(s)). Subsequently thereafter, in the second programming stage, the program states of “Group B” (i.e., States “9” through “15”) are concurrently programmed. Similarly, as shown in table 1030, approximately 12 program loops are required to complete the second programming stage. Thus, according to this particular example, a total of approximately 24 program loops are needed in order to complete the programming of States “1” through “15.” Therefore, the amount of programming time (T_{prog}) consumed in a bifurcated (or otherwise divided) concurrent programming operation is greater than the amount of time that is needed to complete the undivided concurrent programming operation of, for example, the embodiment depicted in FIGS. 17A through 17E. Still yet, the bifurcated programming operation improves upon the total amount of programming time that may be exhausted in a serial programming approach due to the fact that concurrent programming is still utilized within the confines of the program state group divisions.

Turning now to FIG. 18D, there is depicted a signal timing diagram 1040 indicating several voltage signals that are applied during a single programming pulse according to the bifurcated concurrent programming operation of the exemplary embodiment that is described above in connection with FIGS. 18A-18C. As indicated, the signal waveforms set forth in the timing diagram 1040 are substantially identical to the signal waveforms depicted in the signal timing diagram 940 in connection with the embodiment in FIGS. 17A through 17E. The only differences that exist involve the bifurcation of the programming operation into a first stage pertaining only to the program states of “Group A” and a second stage pertaining only to the program states of “Group B.” Accordingly, when concurrently programming just the program states of “Group A,” the signal timing diagram 1040 would only involve the respective bitline voltage bias (V_{BL1}, V_{BL}2, . . . , and V_{BL8}) signals with respect to the bitline(s) that are associated with the program States “1” through “8.” In addition, as described in detail above, the voltage level of the programming voltage bias (V_{PGM}) signal that is applied to the selected word line(s) during this first programming stage is the programming voltage bias level that is suitable for programming the highest program state within “Group A,” i.e., State “8” at a voltage level of V_{PGM8}. By contrast, when concurrently programming just the program states designated for “Group B,” signal timing diagram 1040 would only involve the respective bitline voltage bias (V_{BL9}, V_{BL1}0, . . . , and V_{BL15}) signals with respect to the bitline(s) that are associated with the program States “9” through “15.” Further, the voltage level of the programming voltage bias (V_{PGM}) signal applied to the selected word line(s) in this second programming stage is the programming voltage bias level that is appropriate for programming the highest program state within “Group B,” i.e., State “15” at the comparatively higher voltage level of V_{PGM15}.

With respect to FIG. 18E, there is shown a flow diagram 1050 that, in general terms, outlines several steps of a divided concurrent programming operation that may include, for example, the bifurcated concurrent programming operation according to the exemplary embodiment described above with respect to FIGS. 18A through 18D. As indicated, beginning at step 1052, a programming operation is initiated with respect to a given memory structure. Thereafter, at step 1054, the program states that are to be programmed during the programming operation are then divided into two or more groups, wherein each group comprises a different subset of the program states. Next, at step 1056, for each group, a programming voltage bias suitable for programming the highest program state of that group is then applied to all selected word line(s) of the memory structure. Further, in conjunction with the application of the programming voltage bias (at step 1056) and with respect to each program state of the group, a respective bitline voltage bias is applied to one or more bitline(s) associated with the memory element(s) or cell(s) selected to be programmed to that particular program state (see step 1058). As stated, the magnitude of each bitline voltage bias level applied is pre-determined such that application of the bitline voltage bias subsequently results in a reduction of the programming voltage bias level to an “effective” programming voltage bias level that is suitable for the programming of that particular program state.

In the above description, different programming approaches are discussed above for reducing the programming time needed to complete the operation (thereby improving upon the programming speed) by concurrently programming multiple program states. In the exemplary embodiments above, this is accomplished by adjusting a single high programming voltage bias (V_{PGM}) to an appropriate “effective” voltage level for each program state by way of a variable bitline voltage bias (V_{BL}) applied with respect to each program state. However, as mentioned above, these programming approaches may damage the durability and reliability of the memory structure and the programming operation due to the application of the relatively high voltage biases. Therefore, a further programming approach may be considered that allows for the concurrent programming of multiple states but does not involve the application of high bitline voltage bias (V_{BL}) values.

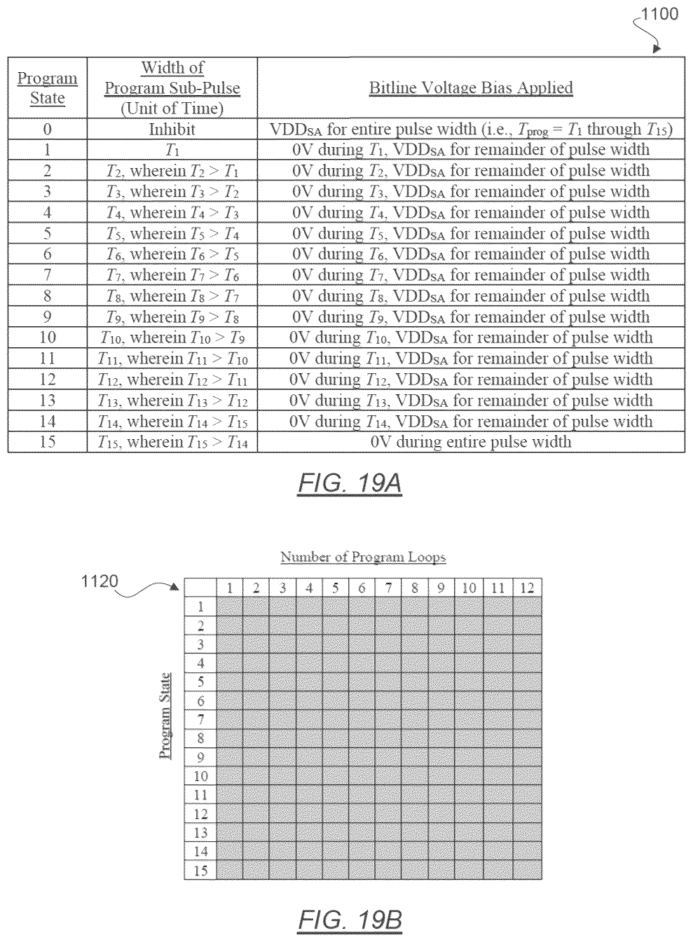

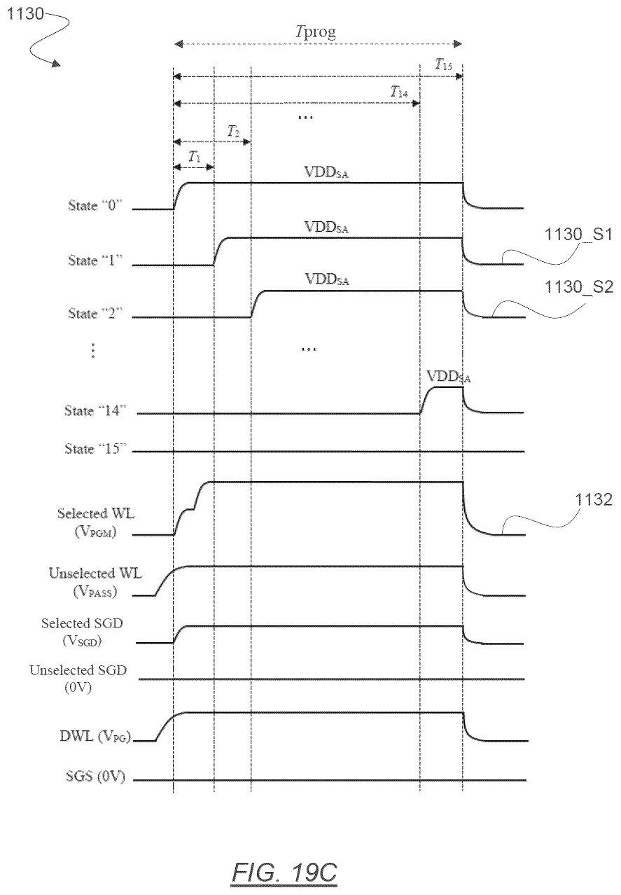

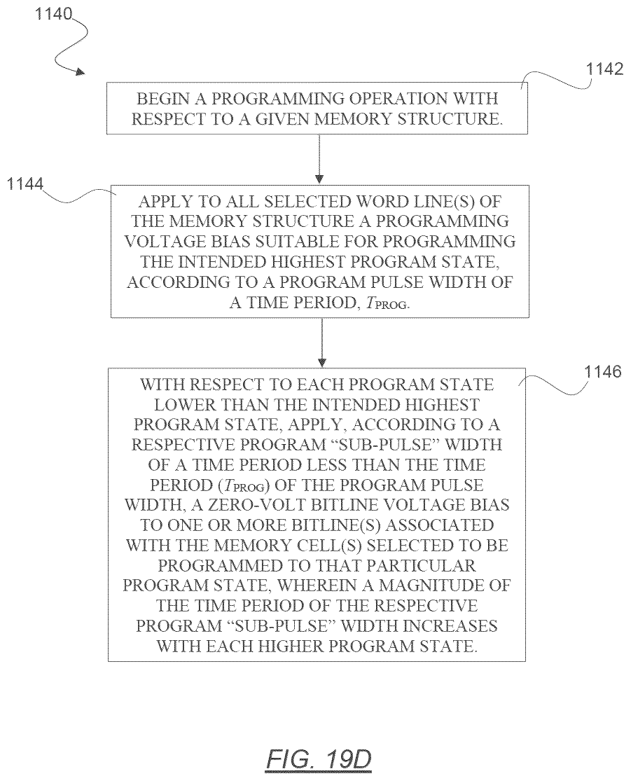

Referring now to FIGS. 19A through 19D, there is depicted a further exemplary embodiment of programming operation that allows for concurrent programming of multiple program states by modifying or dividing the pulse width of a single programming voltage bias signal into several “sub-pulses” or “micro pulses,” with each “sub-pulse” or “micro-pulse” corresponding to one program state. For comparison purposes with the earlier-described concurrent programming approaches, the programming operation according to this particular embodiment is also described below as being applied to a QLC NAND-type memory structure in which there are 16 programmable states (i.e., State “0” (or “erased” state) through State “15”). However, the basic principles generally described below with respect to this programming approach may be applied to a memory structure comprising any type of “multi-level” memory element(s) or cells(s) (e.g., MLC or TLC).

Beginning with FIG. 19A, there is provided a “look-up” table or chart 1100 that, with respect to each program State “0” through “15,” indicates the width of the program sub-pulse associated with that program state, as well as the corresponding bitline voltage bias (V_{BL}) level that is applied during the program pulse period. Importantly, as depicted in the table 1100, the “width” of the program sub-pulse is defined as a period of time, T. Accordingly, beginning with State “0,” the table 1100 indicates that an inhibit condition is applied in order to effectuate an “erased” state.

However, with respect to each of the program States “1” through “15,” a single programming voltage bias (V_{PGM}) level is applied to all selected word line(s). And, in a similar manner to the concurrent programming operations that are depicted in FIGS. 17A and 18A, the magnitude of this programming voltage bias (V_{PGM}) is a voltage level that is determined to be suitable for programming the highest program state, i.e., State “15.” However, unlike the concurrent programming operations described above with respect to FIGS. 17A and 18A, a variable bitline voltage bias (V_{BL}) is not applied in order to moderate the high programming voltage bias (V_{PGM}) in order to suit the programming requirements of the lower program States “1” through “14.” Rather, as indicated in table 1100 of FIG. 19A, the width (or length) of the program pulse period, T, is modified with respect to each program state in order to effectively capture the programming of each program state within a single programming period (T_{prog}). To be more specific, according to experimental and in situ data and observations, a decrease in the width (or length) of the program pulse period (T) results in a slower voltage threshold (Vₜₕ) migration speed of the memory element(s) or cell(s) being programmed. Thus, despite being exposed to the high programming voltage bias (V_{PGM}) level associated with the program State “15,” each of the lower program states may be programmed by incrementally decreasing or shortening the program pulse width (or length or time duration) for each of the lower program States “1” through “14.”

Therefore, with respect to program State “1,” table 1100 of FIG. 19A indicates that during a program “sub-pulse” width of a shortened time period T₁, a bitline voltage bias (V_{BL}) level of zero volts is applied to the bitline(s) associated with the memory element(s) or cell(s) selected to be programmed to program State “1.” Accordingly, the term “sub-pulse” is applied here due to the fact that the time period T₁ is only a fraction of a full program pulse width (T), which may be defined as having a time period of T_{prog}. Thereafter, for the reminder of the full program pulse width (or time period T_{prog}), an inhibit condition is applied to the associated bitline(s). Accordingly, during the program sub-pulse width (time period T₁), the memory element(s) or cell(s) are subjected to the high applied programming voltage bias (V_{PGM}) level. However, the shortened pulse width (time period T₁) is precisely chosen such that the threshold voltage (Vₜₕ) migration of the charges during the time period T₁ only reaches or extends to the threshold voltage (Vₜₕ) distribution corresponding to program State “1.”

Similarly, with respect to program State “2,” a zero volt bitline voltage bias (V_{BL}) level is only applied to the appropriate bitline(s) during a shortened program “sub-pulse” width (or length) of a time period T₂. Thereafter, for the reminder of the full program pulse width (time period T_{prog}), an inhibit condition is applied to the associated bitline(s). According to logic, in order to ensure that there is sufficient time to effectively program the higher State “2,” the time period T₂ must be greater in magnitude than the program “sub-pulse” width (i.e., time period T₁) that is applied for the programming of the lower State “1.” As indicated in the table 1100, the same programming approach is maintained with respect to each of program States “3” through “14.” Specifically, for each increased program state, the associated program “sub-pulse” width (or time period) is incrementally increased relative to the program “sub-pulse” width applied to the next lower program state. Accordingly, as depicted in table 1100, the program “sub-pulse” width (or time period) applied with respect to program State “3” (i.e., time period T₃) is incrementally greater in magnitude relative to the program “sub-pulse” width that is employed with respect to program State “2” (i.e., time period T₂). The same relative difference occurs between the respective program “sub-pulse” widths (or time periods) associated with program State “3” and program State “2,” program State “4” and program State “3,” program State “5” and program State “4,” and so on, through program State “14.” Lastly, as shown in table 1100, as expected, no shortened program “sub-pulse” width is applied with respect to programming program State “15.” Rather, a zero volt bitline voltage bias (V_{BL}) is applied during the entire program pulse width (i.e., time period T_{prog}) such that the programmed memory element(s) or cell(s) are subject to the high programming voltage bias (V_{PGM}) for the full extent of the pulse period, as is necessary in order to program State “15.”

Accordingly, in applying this programming approach, all of the program States “1” through “15” are concurrently programmed within a single program pulse width or period (i.e., time period T_{prog}) by creating, for each program state, what may be considered a program “sub-pulse” width that is within the greater full program pulse width (i.e., time period T_{prog}). Importantly, this concurrent programming operation is accomplished effectively without the introduction of any bitline voltage bias (V_{BL}) level that is greater than zero volts. Thus, the possibility of any detrimental or damaging ramifications to the memory structure and memory operations from the application of significant bitline voltage bias (V_{BL}) levels is substantially avoided.

It should be noted that the magnitude of the incremental change in the program “sub-pulse” width from one program state to another may vary between the program states, or it may be identical between each program state.

Referring now to FIG. 19B, there is illustrated, in a similar manner to FIGS. 17C and 18C, a graphical illustration or representation of the total number of program loops that are required in order to program States “1” through “15” in accordance with the programming operation of the embodiment depicted in FIG. 19A. According to this particular example, only approximately 12 program loops are needed to complete the programming operation due to the ability to concurrently program all of the program states. As such, the programming time (and speed) that may be achieved according to this programming approach is much improved over a serial programming approach and is substantially similar to the programming time (and speed) achieved using the programming approach previously described with respect to FIGS. 17A-17E. As mentioned however, the programming approach according to the embodiment in FIG. 19A beneficially does not require the application of any bitline voltage bias levels.

Referring now to FIG. 19C, depicted therein is a signal timing diagram 1130 that indicates the various voltage bias signals that are applied during a single programming pulse (having time period T_{prog}) in accordance with the programming operation of the embodiment depicted in FIGS. 19A and 19B. Accordingly, voltage signal 1132 comprises the single programming voltage bias (V_{PGM}) level applied to all selected word line(s) of the memory structure, wherein, as mentioned above, the magnitude of the programming voltage bias (V_{PGM}) level is pre-determined as being suitable for effectively programming the highest program state. In this particular example, the highest program state is State “15.” Further, as indicated in the signal timing diagram 1130, an incrementally shortened program “sub-pulse” width (i.e., time period T₁, T₂, . . . , T₁₄) is correspondingly applied with respect to each of program States “1” through “14.” It should be noted that for the sake of brevity and illustrative clarity, the bitline voltage bias signal associated with each and every program state is not shown in signal timing diagram 1130. Only a general framework is depicted. According, as indicated with respect to program State “1,” a zero-voltage bitline voltage bias signal 1130_S1 is applied during the time period T₁. Further, as indicated with respect to program State “2,” a zero-voltage bitline voltage bias signal 1130_S2 is applied during the time period T₂, wherein T₂ is larger than T₁. And, with respect to the remaining program States “3” through “14,” an identical pattern is followed. Namely, with each higher program state, there is an incremental increase in the time period in which the respective zero-voltage bitline voltage bias (V_{BL}) level is applied in the manner described in detail above with respect to FIG. 19A.

With respect to FIG. 19D, there is shown a flow diagram 1140 that, in general terms, outlines several steps of a “bitline timing based concurrent” programming operation, such as the embodiment depicted in FIGS. 19A-19C. As indicated, beginning at step 1142, a programming operation is initiated with respect to a given memory structure. Thereafter, at step 1144, a programming voltage bias that is suitable for programming the intended highest program state is applied to all of the selected word line(s) of the memory structure according to a program pulse width of a time period, T_{prog}. In addition, at step 1146, with respect to each program state that is lower than the highest program state, a zero-volt bitline voltage bias is applied to one or more bitline(s) associated with the memory element(s) or cell(s) selected to be programmed to that particular program state. Further, as indicated, the zero-volt bitline voltage bias is applied with respect to each program state according to a respective program “sub-pulse” width having a time period that is less than the time period (T_{prog}) of the program pulse width, and wherein the magnitude of the time period of the respective program “sub-pulse” width increases with each higher program state.

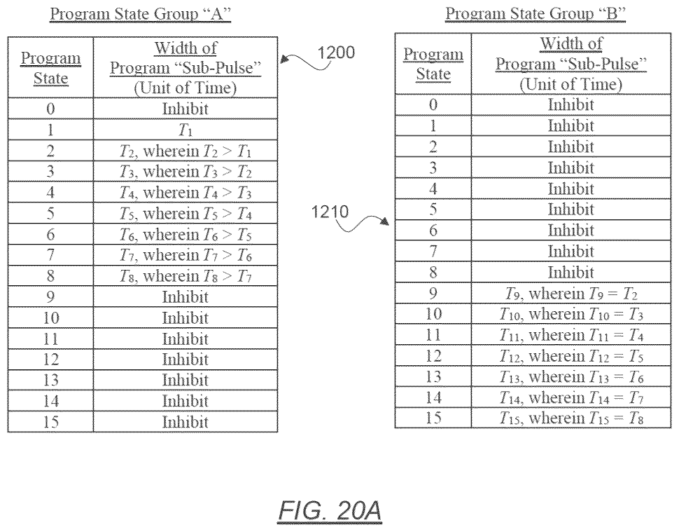

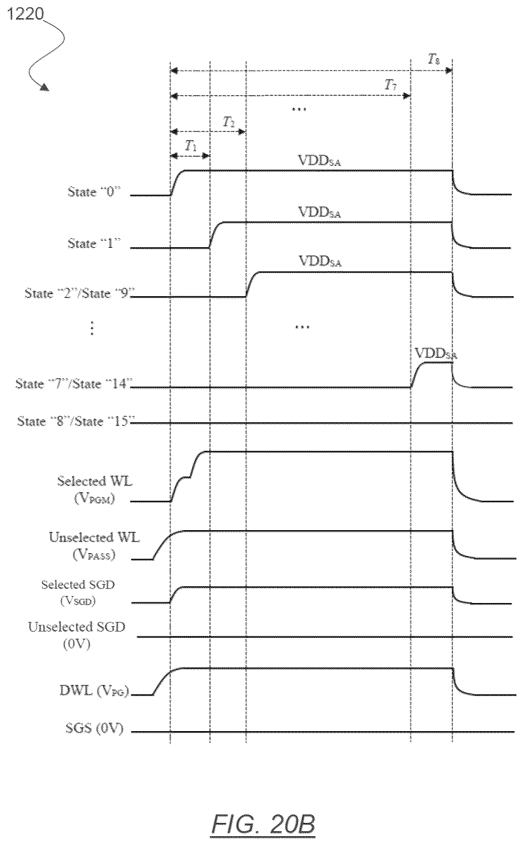

Further, the “bitline timing based concurrent” programming approach according to the exemplary embodiment of FIGS. 19A through 19D may also be applied in cases in which the program states have been divided or partitioned into separate groups or subsets. An illustrative example of such a case is depicted in FIGS. 20A and 20B. With respect to FIG. 20A, there is provided a first “look-up” table or chart 1200 and a second “look-up” table or chart 1210, which are to be applied during a programming operation. As is apparent from the two tables 1200 and 1210, such a programming operation is separated into two programming stages. In the first programming stage, as indicated in table 1200, the program States “0” through “8” are programmed in a manner substantially similar to the “bitline timing based concurrent” programming approach of the embodiment that is depicted in FIGS. 19A through 19D. During this first programming stage, the programming voltage bias (V_{PGM}) level that is applied to the selected word line(s) is the voltage level that is pre-determined as suitable for programming the highest program state that is within this first programming stage, i.e., Stage “8.” Further, with respect to program States “9” through “15,” an inhibit condition is imposed such that those program states are not programmed during the first programming stage. Next, in a second programming stage, program States “9” through “15” are programmed also in a manner substantially similar to the “bitline timing based concurrent” programming approach of the embodiment that is depicted in FIGS. 19A through 19D. As a result, the program States “1” through “8” are concurrently programmed during the first programming stage. As indicated in table 1210, the programming voltage bias (V_{PGM}) level that is applied to all selected word line(s) during this second programming stage is the voltage level that is pre-determined as being appropriate for programming the highest program state that is within this second programming stage, i.e., Stage “15.” Further, with respect to the program States “1” through “8,” an inhibit condition is imposed such that those program states are not programmed during the second programming stage. As a result, the program States “9” through “15” are concurrently programmed during the second programming stage. In a corresponding manner, FIG. 20B is a signal timing diagram 1220 that indicates the various voltage bias signals applied during the bifurcated “bitline timing based concurrent” programming operation indicated in FIG. 20A. Therefore, a “bitline timing based concurrent” programming operation, such as the exemplary embodiment depicted in FIGS. 19A through 19D, may be equally applied to separate subsets or groups of program states.

The above discussion is meant to be illustrative of the principles and various embodiments of the present invention. Numerous variations and modifications will become apparent to those skilled in the art once the above disclosure is fully appreciated. For example, although on-memory controllers have been described as performing or controlling the methods that are described above, any processor executing software within a host system can perform the methods described above without departing from the scope of the disclosure. In particular, the methods and techniques described herein as performed in the on-memory controller(s), may also be performed in a host. Furthermore, the methods and concepts disclosed herein may be applied to other types of persistent memories other than flash. It is intended that the following claims be interpreted to embrace all such variations and modifications.

What is claimed is:

1. A method for multi-state programming of a memory structure, the method comprising:
initiating a programming operation with respect to multiple program states of a non-volatile memory structure, the memory structure comprising a plurality of memory elements;
applying, to all selected word lines of the memory structure, a programming voltage bias (V_{PGM}) level pre-determined to be suitable for programming a highest program state of the multiple program states, wherein the programming voltage bias is applied according to a given program pulse width; and
with respect to each program state other than the highest program state of the multiple program states, applying a zero-volt bitline voltage bias (V_{BL}) to one or more bitlines associated with one or more of the memory elements selected to be programmed to the program state, wherein the zero-volt bitline voltage bias (V_{BL}) is applied according to a respective program sub-pulse width that is less than the given program pulse width.

2. The method according to claim 1, wherein a magnitude of the respective program sub-pulse width increases an incremental amount with each higher program state.

3. The method according to claim 2, wherein the incremental amount is identical between each program state.

4. The method according to claim 2, wherein the incremental amount is nonidentical between each program state.

5. The method according to claim 1, further comprising pre-determining a magnitude of the respective program sub-pulse width such that the program state is effectively programmed according to the programming voltage bias (V_{PGM}).

6. The method according to claim 1, wherein the multiple program states are concurrently programmed within the given program pulse width.

7. The method according to claim 1, wherein the memory structure comprises a plurality of NAND-type memory cells.

8. A memory controller, comprising:
a communication pathway configured to couple to a non-volatile memory structure, wherein the memory structure comprises a plurality of memory elements;
the memory controller configured to:
initiate a programming operation with respect to multiple program states of the memory structure;
apply, to all selected word lines of the memory structure, a programming voltage bias (V_{PGM}) level pre-determined to be suitable for programming a highest program state of the multiple program states, wherein the programming voltage bias is applied according to a given program pulse width; and
with respect to each program state other than the highest program state of the multiple program states, apply a zero-volt bitline voltage bias (V_{BL}) to one or more bitlines associated with one or more of the memory elements selected to be programmed to the program state, wherein the zero-volt bitline voltage bias (V_{BL}) is applied according to a respective program sub-pulse width that is less than the given program pulse width.

9. The memory controller according to claim 8, wherein a magnitude of the respective program sub-pulse width increases an incremental amount with each higher program state.

10. The memory controller according to claim 9, wherein the incremental amount is identical between each program state.

11. The memory controller according to claim 9, wherein the incremental amount is nonidentical between each program state.

12. The memory controller according to claim 8, wherein a magnitude of the respective program sub-pulse width is pre-determined such that the program state is effectively programmed according to the programming voltage bias (V_{PGM}).

13. The memory controller according to claim 8, wherein the multiple program states are concurrently programmed within the given program pulse width.

14. The memory controller according to claim 8, wherein the memory structure comprises a plurality of NAND-type memory cells.

15. A non-volatile memory system, comprising:
a memory structure comprising a population of NAND-type memory elements; and
a memory controller coupled to the memory structure and:
initiating a programming operation with respect to multiple program states of the memory structure;
applying, to all selected word lines of the memory structure, a programming voltage bias (V_{PGM}) level pre-determined to be suitable for programming a highest program state of the multiple program states, wherein the programming voltage bias is applied according to a given program pulse width; and
with respect to each program state other than the highest program state of the multiple program states, applying a zero-volt bitline voltage bias (V_{BL}) to one or more bitlines associated with one or more of the memory elements selected to be programmed to the program state, wherein the zero-volt bitline voltage bias (V_{BL}) is applied according to a respective program sub-pulse width that is less than the given program pulse width.

16. The non-volatile memory system according to claim 15, wherein a magnitude of the respective program sub-pulse width increases an incremental amount with each higher program state.

17. The non-volatile memory system according to claim 16, wherein the incremental amount is identical between each program state.

18. The non-volatile memory system according to claim 16, wherein the incremental amount is nonidentical between each program state.

19. The non-volatile memory system according to claim 15, wherein a magnitude of the respective program sub-pulse width is pre-determined such that the program state is effectively programmed according to the programming voltage bias (V_{PGM}).

20. The non-volatile memory system according to claim 15, wherein the multiple program states are concurrently programmed within the given program pulse width.
